(19) United States
(12) Patent Application Publication
(10) Pub. No.: US 2026/0319295 A1
(43) Pub. Date: Oct. 15, 2026

(54) LIGHT-EMITTING SUBSTRATE AND METHOD FOR MANUFACTURING THE SAME, AND DISPLAY DEVICE

(71) Applicants: HEFEI BOE RUISHENG TECHNOLOGY CO., LTD., Anhui (CN); BOE TECHNOLOGY GROUP CO., LTD., Beijing (CN)

(72) Inventors: Haifeng HU, Beijing (CN); Huan LIU, Beijing (CN); Xin ZHA, Beijing (CN); Ting ZENG, Beijing (CN); Tao XIAO, Beijing (CN); Renwei ZHANG, Beijing (CN); Junyi CAO, Beijing (CN); Caigui YANG, Beijing (CN); Xiaoxiao LIU, Beijing (CN); Xin LI, Beijing (CN); Wei JIANG, Beijing (CN); Chaolei REN, Beijing (CN); Xiaoxiao CHEN, Beijing (CN); Fang LU, Beijing (CN); Haixin WANG, Beijing (CN); Wei WANG, Beijing (CN); Jianying ZHANG, Beijing (CN); Hao ZHONG, Beijing (CN)

(73) Assignees: HEFEI BOE RUISHENG TECHNOLOGY CO., LTD., Anhui (CN); BOE TECHNOLOGY GROUP CO., LTD., Beijing (CN)

(21) Appl. No.: 18/996,022

(22) PCT Filed: Apr. 30, 2024
(86) PCT No.: PCT/CN2024/090834

§ 371 Date: Jan. 17, 2025

(30) Foreign Application Priority Data
Nov. 29, 2023 (WO) PCT/CN2023/135033
Dec. 29, 2023 (WO) PCT/CN2023/143434

(51) Int. Cl. G02F 1/1335; G02F 1/13357

(52) U.S. Cl. CPC G02F 1/133612; G02F 1/133603

(57) ABSTRACT

A light-emitting substrate and a method for manufacturing the same, and a display device are provided. In the light-emitting substrate, the first electrode includes a cover portion not exposed by the first via hole, the cover portion of the first electrode includes an upper surface away from the base substrate, a first included angle is between a surface where the first slope surface is located and the upper surface of the cover portion, a second included angle is between a surface where the second slope surface is located and the upper surface of the cover portion, and the second included angle is greater than the first included angle; and the first electrode and the second electrode of the electrical connection structure provide an electrical signal to the light-emitting device for driving the light-emitting device to emit light.

The application claims priority to the international application PCT/CN2023/135033 filed on Nov. 29, 2023 and the international application PCT/CN2023/143434 filed on Dec. 29, 2023, the entire disclosure of which is incorporated herein by reference as part of the present application.

### TECHNICAL FIELD

At least one embodiment of the present disclosure relates to a light-emitting substrate and a method for manufacturing the light-emitting substrate, and a display device.

### BACKGROUND

LEDs (light-emitting diodes) have advantages such as low cost, high luminous efficiency, and being energy-saving and environmentally friendly, making them widely used in scenarios such as lighting, visible light communication, and light-emitting display.

One development direction for LEDs is towards miniaturization and microminiaturization. When scaled down, LEDs form arrays with millimeter-level or even micrometer-level spacing, achieving ultra-high resolution, which allows for broader applications in fields such as information display.

Currently, small-sized flip-chip LED chips are widely used in backlight display devices and RGB display devices, and display products on the market are all mounted upside down on a circuit substrate with thousands or tens of thousands of flip-chip LED chips with individual light-emitting units or flip-chip LED chips with two serially connected light-emitting units. As the chip size decreases and the distance between the dies becomes closer, the resulting display contrast increases.

In miniaturized LED light-emitting panels, a single metal layer may be used for electrical connection with the LEDs to provide a light-emitting signal, or double metal layers may also be used for electrical connection with the LEDs to provide the light-1 emitting signal. A first metal layer in the double metal layers is electrically connected to a circuit board in a bonding region, and a second metal layer in the double metal layers is electrically connected to the first metal layer through via holes, thereby overlapping with and electrically connecting to the first metal layer. Compared to the single metal layer configuration, the double metal layers configuration facilitates layered wiring, offering higher flexibility and variety in wiring, which enables more partitions and finer control of the light-emitting substrate. However, it is necessary to ensure the reliability of the overlap connection between the double metal layers through via holes.

### SUMMARY

At least one embodiment of the present disclosure provides a light-emitting substrate, which includes a base substrate, a light-emitting device, and an electrical connection structure. The base substrate has a main surface, and includes a light-emitting region and a non-light-emitting region at least partially surrounding the light-emitting region; the light-emitting device is provided on the main surface of the base substrate and in the light-emitting region; and the electrical connection structure includes a first electrode, an inorganic insulation layer, and a second electrode. The first electrode is on the main surface of the base substrate; the inorganic insulation layer is stacked with the first electrode in a vertical direction perpendicular to the main surface of the base substrate, and is on a side of the first electrode away from the main surface of the base substrate, and the inorganic insulation layer includes a first via hole exposing the first electrode; the second electrode is stacked with the first electrode and the inorganic insulation layer in the vertical direction, is on a side of the inorganic insulation layer away from the first electrode, and is electrically connected to the first electrode through the first via hole; the inorganic insulation layer includes a first sub-portion and a second sub-portion that are arranged in the vertical direction, and the second sub-portion is on a side of the first sub-portion away from the base substrate; the first sub-portion includes a first slope surface surrounding the first via hole, and the second sub-portion includes a second slope surface surrounding the first via hole; and the first electrode includes a cover portion not exposed by the first via hole, the cover portion of the first electrode includes an upper surface away from the base substrate, a first included angle is formed between a surface where the first slope surface is located and the upper surface of the cover portion, a second included angle is formed between a surface where the second slope surface is located and the upper surface of the cover portion, and the second included angle is greater than the first included angle.

For example, in the light-emitting substrate provided by at least one embodiment of the present disclosure, a thickness of the second sub-portion in the vertical direction is less than a thickness of the first sub-portion in the vertical direction.

For example, in the light-emitting substrate provided by at least one embodiment of the present disclosure, a ratio of the thickness of the second sub-portion in the vertical direction to a thickness of the inorganic insulation layer in the vertical direction is less than or equal to ⅓.

For example, in the light-emitting substrate provided by at least one embodiment of the present disclosure, the inorganic insulation layer comprises a first sub-inorganic insulation layer and a second sub-inorganic insulation layer stacked on each other in the vertical direction; the second sub-inorganic insulation layer is on a side of the first sub-inorganic insulation layer away from the base substrate, and the first via hole penetrates through the first sub-inorganic insulation layer and the second sub-inorganic insulation layer; and the second sub-inorganic insulation layer comprises an upper portion and a lower portion, the lower portion is in contact with the first sub-inorganic insulation layer, the upper portion is on a side of the lower portion away from the first sub-inorganic insulation layer, the upper portion serves as the second sub-portion, and a whole structure constituted by the lower portion and the first sub-inorganic insulation layer serves as the first sub-portion.

For example, the light-emitting substrate provided by at least one embodiment of the present disclosure further comprises a first organic insulation layer, the first organic insulation layer is between the first sub-inorganic insulation layer and the second sub-inorganic insulation layer, and comprising a second via hole; an orthographic projection of the first via hole on the base substrate falls within an orthographic projection of the second via hole on the base substrate, the first organic insulation layer comprises an upper surface away from the base substrate and a side surface facing the first via hole, and the second sub-inorganic insulation layer covers the upper surface and the side surface of the first organic insulation layer; and a portion of the first sub-inorganic insulation layer close to the first via hole comprises a first edge portion exposed by the second via hole, a portion of the second sub-inorganic insulation layer covering the side surface of the first organic insulation layer is a second edge portion, the second edge portion further covers the first edge portion and is in contact with the first edge portion, and a whole structure constituted by the first edge portion and the second edge portion comprises the first slope surface and the second slope surface.

For example, in the light-emitting substrate provided by at least one embodiment of the present disclosure, the first included angle is a slope angle of the first slope surface, and the second included angle is a slope angle of the second slope surface; and the first slope surface comprises a junction position of the first edge portion and the second edge portion, and a slope angle of the first slope surface at the junction position is equal to a slope angle of the entire first slope surface.

For example, in the light-emitting substrate provided by at least one embodiment of the present disclosure, the first included angle is in a range of 15° to 30°, and the second included angle is in a range of 50° to 80°.

For example, in the light-emitting substrate provided by at least one embodiment of the present disclosure, a portion of the second electrode in the first via hole comprises a lower surface and a side surface; the lower surface of the second electrode is in contact with the first electrode, and no bubbles, gaps or impurities are between the lower surface of the second electrode and the first electrode; and the side surface of the second electrode is in contact with both the first slope surface and the second slope surface, and no bubbles, gaps or impurities are between the side surface of the second electrode and the first slope surface as well as the second slope surface.

For example, in the light-emitting substrate provided by at least one embodiment of the present disclosure, a material of the inorganic insulation layer comprises at least one selected from a group consisting of silicon nitride, silicon oxide and silicon oxynitride, and materials of the first electrode and the second electrode are both copper.

For example, in the light-emitting substrate provided by at least one embodiment of the present disclosure, the light-emitting device comprises a first electrode pin and a second electrode pin; the light-emitting substrate further comprises a circuit board in the non-light-emitting region, the first electrode of the first electrical connection structure is electrically connected to the circuit board to receive a power signal from the circuit board, the second electrode of the first electrical connection structure is electrically connected to the first electrode pin of the light-emitting device to provide the power signal to the light-emitting device, and the power signal is the electrical signal used to drive the light-emitting device to emit light.

For example, in the light-emitting substrate provided by at least one embodiment of the present disclosure, the light-emitting substrate comprises a first conductive layer and a second conductive layer, the first conductive layer comprises the first electrode, and the second conductive layer comprises the second electrode; the light-emitting substrate further comprises a driving circuit, and the driving circuit is at least partially in the light-emitting region; and the second conductive layer further comprises a connection electrode, a first end of the connection electrode is electrically connected to the driving circuit, a second end of the connection electrode is electrically connected to the second electrode pin of the light-emitting device to provide a light-emitting driving signal to the light-emitting device, and the light-emitting device is driven by the power signal and the light-emitting driving signal to emit light.

For example, in the light-emitting substrate provided by at least one embodiment of the present disclosure, the light-emitting substrate comprises a plurality of the electrical connection structures, the plurality of the electrical connection structures further comprise a second electrical connection structure, and the second electrical connection structure comprises the first electrode and the second electrode of the electrical connection structure; the light-emitting substrate further comprises a driving circuit, and the driving circuit is at least partially in the light-emitting region; the light-emitting substrate comprises a light-emitting array, the light-emitting array comprises a plurality of light-emitting units arranged in an array, each light-emitting unit comprises a plurality of the light-emitting devices, and the driving circuit is provided corresponding to each light-emitting unit to control light-emitting condition of the light-emitting device of the each light-emitting unit; the plurality of light-emitting units of the light-emitting array comprise a first light-emitting unit and a second light-emitting unit that are in a same column; the first electrode of the second electrical connection structure is electrically connected to the circuit board to receive a light-emitting control signal from the circuit board, the second electrode of the second electrical connection structure is electrically connected to an input terminal of the driving circuit corresponding to the first light-emitting unit, and the light-emitting control signal comprises a light-emitting driving signal for controlling light-emitting state of the light-emitting device and/or a timing control signal for controlling the light-emitting device to emit light; the plurality of the electrical connection structures further comprise a third electrical connection structure, and the third electrical connection structure comprises the first electrode and the second electrode of the electrical connection structure; the second electrode of the third connection structure is electrically connected to an output terminal of the driving circuit corresponding to the first light-emitting unit, and the first electrode of the third electrical connection structure is electrically connected to an input terminal of the driving circuit corresponding to the second light-emitting unit to provide the light-emitting control signal to the second light-emitting unit.

For example, in the light-emitting substrate provided by at least one embodiment of the present disclosure, the plurality of the electrical connection structures further comprise a fourth electrical connection structure, and the fourth electrical connection structure comprises the first electrode and the second electrode of the electrical connection structure; and the first electrode of the fourth electrical connection structure is grounded, and the second electrode of the fourth electrical connection structure is electrically connected to a ground signal input terminal of the driving circuit.

For example, in the light-emitting substrate provided by at least one embodiment of the present disclosure, the light-emitting device is a mini light-emitting diode (referred to as Mini LED) or a micro light-emitting diode (referred to as Micro LED).

At least one embodiment of the present disclosure further provides a display device, and the display device comprises any one of the light-emitting substrates provided by the embodiments of the present disclosure. The light-emitting substrate is a display substrate, the light-emitting region is a display region and comprises a sub-pixel, and the sub-pixel comprises the light-emitting device; the electrical signal provided by the first electrode and the second electrode of the first electrical connection structure to the light-emitting device for driving the light-emitting device to emit light is a display driving signal to drive the light-emitting device to display an image; or, the light-emitting substrate serves as a backlight source of the display device and is configured to provide light for display to the display substrate.

At least one embodiment of the present disclosure further provides a method for manufacturing a light-emitting substrate, and the method comprises: providing a base substrate, wherein the base substrate has a main surface, and comprises a light-emitting region and a non-light-emitting region at least partially surrounding the light-emitting region; providing a light-emitting device on the main surface of the base substrate, in which the light-emitting device is in the light-emitting region; and forming an electrical connection structure on the main surface of the base substrate, which comprises: forming a first electrode on the main surface of the base substrate; forming an inorganic insulation layer, in which the inorganic insulation layer is stacked with the first electrode in a vertical direction perpendicular to the main surface of the base substrate, and is on a side of the first electrode away from the main surface of the base substrate; forming a first via hole penetrating through the inorganic insulation layer, in which the first via hole exposes the first electrode; and forming a second electrode, in which the second electrode is stacked with the first electrode and the inorganic insulation layer in the vertical direction and is on a side of the inorganic insulation layer away from the first electrode, and is electrically connected to the first electrode through the first via hole; the inorganic insulation layer comprises a first sub-portion and a second sub-portion that are arranged in the vertical direction, and the second sub-portion is on a side of the first sub-portion away from the base substrate; the first sub-portion comprises a first slope surface surrounding the first via hole, and the second sub-portion comprises a second slope surface surrounding the first via hole; the first electrode comprises a cover portion not exposed by the first via hole, the cover portion of the first electrode comprises an upper surface away from the base substrate, a first included angle is formed between a surface where the first slope surface is located and the upper surface of the cover portion, a second included angle is formed between a surface where the second slope surface is located and the upper surface of the cover portion, and the second included angle is greater than the first included angle; and the electrical connection structure comprises a first electrical connection structure, the first electrical connection structure comprises the first electrode and the second electrode, and the first electrode and the second electrode of the first electrical connection structure are configured to provide an electrical signal to the light-emitting device for driving the light-emitting device to emit light.

At least one embodiment of the present disclosure further provides a method for manufacturing a light-emitting substrate, and the method comprises: providing a base substrate, in which the base substrate has a main surface, and comprises a light-emitting region and a non-light-emitting region at least partially surrounding the light-emitting region; providing a light-emitting device on the main surface of the base substrate, wherein the light-emitting device is in the light-emitting region; and forming an electrical connection structure on the main surface of the base substrate, which comprises: forming a first electrode on the main surface of the base substrate; forming an inorganic insulation layer, wherein the inorganic insulation layer is stacked with the first electrode in a vertical direction perpendicular to the main surface of the base substrate, and is on a side of the first electrode away from the main surface of the base substrate; forming a first via hole penetrating through the inorganic insulation layer, in which the first via hole exposes the first electrode; and forming a second electrode, in which the second electrode is stacked with the first electrode and the inorganic insulation layer in the vertical direction and is on a side of the inorganic insulation layer away from the first electrode, and is electrically connected to the first electrode through the first via hole; the inorganic insulation layer comprises a first sub-portion and a second sub-portion that are arranged in the vertical direction, and the second sub-portion is on a side of the first sub-portion away from the base substrate; the first sub-portion comprises a first slope surface surrounding the first via hole, and the second sub-portion comprises a second slope surface surrounding the first via hole; the first electrode comprises a cover portion not exposed by the first via hole, the cover portion of the first electrode comprises an upper surface away from the base substrate, a first included angle is formed between a surface where the first slope surface is located and the upper surface of the cover portion, a second included angle is formed between a surface where the second slope surface is located and the upper surface of the cover portion, and the second included angle is greater than the first included angle; forming the inorganic insulation layer comprises: forming an inorganic material layer, and performing dry etching on the inorganic material layer; the dry etching comprises: in a first dry etching stage, performing dry etching on the inorganic material layer under a first oxygen concentration condition; and in a second dry etching stage after the first dry etching stage, continuing to perform dry etching on the inorganic material layer after the first dry etching stage under a second oxygen concentration condition, in which gases used in both the first dry etching stage and the second dry etching stage comprise oxygen, an oxygen concentration of the gas used in the first dry etching stage is the first oxygen concentration, an oxygen concentration of the gas used in the second dry etching stage is the second oxygen concentration, and the first oxygen concentration is greater than the second oxygen concentration.

For example, in the method for manufacturing a light-emitting substrate provided by at least one embodiment of the present disclosure, forming the inorganic insulation layer comprises: forming a first sub-inorganic material layer after forming the first electrode; forming an organic insulation layer, and forming a second via hole penetrating through the organic insulation layer, wherein an orthographic projection of the first via hole on the base substrate falls within an orthographic projection of the second via hole on the base substrate, and the first organic insulation layer comprises an upper surface away from the base substrate and a side surface facing the first via hole; forming a second sub-inorganic material layer, in which the second sub-inorganic material layer is stacked and in contact with the first sub-inorganic material layer in the vertical direction, and s structure constituted by the first sub-inorganic material layer and the second sub-inorganic material layer serves as the inorganic material layer; and performing the dry etching on the inorganic material layer composed of the first sub-inorganic material layer and the second sub-inorganic material layer, in which the dry etching comprises the first dry etching stage and the second dry etching stage.

For example, in the method for manufacturing a light-emitting substrate provided by at least one embodiment of the present disclosure, in the first dry etching stage and the second dry etching stage, gases used for dry etching comprise oxygen and an auxiliary gas, and the oxygen concentration is a ratio of the oxygen to a total amount of the oxygen and the auxiliary gas; and the first oxygen concentration ranges from 60% to 80%, and the second oxygen concentration ranges from 8% to 25%.

For example, in the method for manufacturing a light-emitting substrate provided by at least one embodiment of the present disclosure, a duration of the second dry etching stage is less than a duration of the first dry etching stage.

For example, in the method for manufacturing a light-emitting substrate provided by at least one embodiment of the present disclosure, at the end of the first dry etching stage, the upper surface of the first electrode is not yet exposed, and the method then enters the second dry etching stage in this time; or, at the end of the first dry etching stage, the upper surface of the first electrode is just exposed, the method then enters the second dry etching stage in this time.

At least one embodiment of the present disclosure provides a light-emitting substrate, and the light-emitting substrate includes a base substrate, a light-emitting device and an electrical connection structure. The base substrate has a main surface, and the light-emitting substrate includes a light-emitting region and a non-light-emitting region at least partially surrounding the light-emitting region; the light-emitting device is arranged on the main surface of the substrate and located in the light-emitting region; the electrical connection structure comprises a first electrode and an inorganic insulation layer; the first electrode is located on the main surface of the substrate; the first electrode of the inorganic insulate layer are stacked in a vertical direction perpendicular to the main surface of the base substrate, and is located at one side of the first electrode away from the main surface of the base substrate; the first electrode has an upper surface away from the base substrate, the inorganic insulation layer covers the upper surface of the first electrode, a first slit is between the inorganic insulation layer and the upper surface of the first electrode, and the width of the first slit is less than 0.2 μm.

For example, in the light-emitting substrate provided by at least one embodiment of the present disclosure, the width of the first slit is less than 0.1 μm.

For example, in the light-emitting substrate provided by at least one embodiment of the present disclosure, the width of the first slit is less than 0.05 μm.

For example, in the light-emitting substrate provided by at least one embodiment of the present disclosure, the first electrode further has a side surface intersecting with the upper surface, and the inorganic insulation layer covers the side surface of the first electrode, and a second slit is between the inorganic insulation layer and the side surface of the first electrode, and the width of the second slit is less than 0.2 μm.

For example, in the light-emitting substrate provided by at least one embodiment of the present disclosure, the width of the second slit is less than 0.1 μm.

For example, in the light-emitting substrate provided by at least one embodiment of the present disclosure, the width of the second slit is less than 0.05 μm.

For example, in the light-emitting substrate provided by at least one embodiment of the present disclosure, the inorganic insulation layer includes a top portion and a side portion, and the top portion of the inorganic insulation layer covers the upper surface of the first electrode, and the side portion of the inorganic insulation layer is connected with the top portion of the inorganic insulation layer and covers the side surface of the first electrode, and the top portion of the inorganic insulation layer includes a main body portion and a protrusion portion, and the main body portion covers the upper surface of the first electrode, and the protrusion portion extends from the main body portion along a horizontal direction parallel to the main surface of the base substrate and protrudes from the main body portion and the side surface.

For example, in the light-emitting substrate provided by at least one embodiment of the present disclosure, a thickness of the inorganic insulation layer is within a preset range, and with the increase of the thickness of the inorganic insulation layer, the length of the protrusion in the horizontal direction becomes smaller.

For example, in the light-emitting substrate provided by at least one embodiment of the present disclosure, the preset range at least includes a range of 1200 Angstroms 3500 Angstroms.

For example, in the light-emitting substrate provided by at least one embodiment of the present disclosure, the inorganic insulation layer includes a top portion and a side portion, the top portion of the inorganic insulation layer covers the upper surface of the first electrode, and the side portion of the inorganic insulation layer is connected with the top portion of the inorganic insulation layer and covers the side surface of the first electrode; the inorganic insulation layer has an interface portion located at a junction position of the top portion and the side portion, the interface portion corresponds to an edge of the first electrode away from the base substrate, and the top the interface portion and the side the interface portion are continuously connected, and the interface portion is dense and has no cracks.

For example, in the light-emitting substrate provided by at least one embodiment of the present disclosure, an included angle between a surface of the side portion and the main surface of the base substrate ranges from 50 degrees to 60 degrees, and the thickness of the first electrode is 2.7 μm; or, an included angle between the surface of the side portion and the main surface of the base substrate ranges from 55 degrees to 65 degrees, and the thickness of the first electrode is 3.6 μm.

For example, in the light-emitting substrate provided by at least one embodiment of the present disclosure, the electrical connection structure further comprises a buffer layer stacked with the first electrode in the vertical direction; the thickness of the buffer layer ranges from 2000 angstroms to 2800 angstroms, and the stress of the buffer layer ranges from −360 MPa to −440 MPa; or, the thickness of the buffer layer ranges from 3600 angstroms to 4500 angstroms, and the stress of the buffer layer ranges from −360 MPa to −440 MPa; or, the thickness of the buffer layer ranges from 4600 angstroms to 5400 angstroms, and the stress of the buffer layer ranges from −360 MPa to −440 MP; or, the thickness of the buffer layer ranges from 5800 angstroms to 6200 angstroms, and the stress range of the buffer layer is less than −800 Mpa.

For example, in the light-emitting substrate provided by at least one embodiment of the present disclosure, the thickness of the first electrode ranges from 1.8 μm to 3.6 μm.

For example, in the light-emitting substrate provided by at least one embodiment of the present disclosure, the inorganic insulation layer includes an edge portion which is stacked and contacted with the buffer layer in the vertical direction.

For example, in the light-emitting substrate provided by at least one embodiment of the present disclosure, the material of the inorganic insulation layer includes at least one selected from a group consisting of silicon nitride, silicon oxide or silicon oxynitride; the material of the buffer layer comprises at least one selected from a group consisting of silicon nitride, silicon oxide or silicon oxynitride; the material of the first electrode is copper.

For example, in the light-emitting substrate provided by at least one embodiment of the present disclosure, the base substrate is a glass substrate, and the glass substrate does not include components of sodium (Na) and calcium (Ca).

For example, in the light-emitting substrate provided by at least one embodiment of the present disclosure, the electrical connection structure further comprises a second electrode which is stacked with the first electrode and the inorganic insulation layer in the vertical direction, located on a side of the inorganic insulation layer away from the first electrode, and electrically connected with the first electrode through a first via hole penetrating the inorganic insulation layer.

For example, in the light-emitting substrate provided by at least one embodiment of the present disclosure, the inorganic insulation layer includes a first sub-inorganic insulation layer and a second sub-inorganic insulation layer stacked on each other in the vertical direction, the second sub-inorganic insulation layer is located at a side of the first sub-inorganic insulation layer away from the base substrate, and the first via hole penetrates the first sub-inorganic insulation layer and the second sub-inorganic insulation layer.

For example, in the light-emitting substrate provided by at least one embodiment of the present disclosure, the thickness of the first inorganic insulation layer is greater than 4000 angstroms.

For example, in the light-emitting substrate provided by at least one embodiment of the present disclosure, the electrical connection structure includes a first electrical connection structure, the first electrical connection structure includes the first electrode and the second electrode, and the first electrode of the first electrical connection structure and the second electrode of the first electrical connection structure are configured to provide the light-emitting device with an electrical signal for driving the light-emitting device to emit light.

For example, in the light-emitting substrate provided by at least one embodiment of the present disclosure, the light-emitting device includes a first electrode pin and a second electrode pin; the light-emitting substrate further comprises a circuit board located in the non-light-emitting region, a first electrode of the first electrical connection structure is electrically connected with the circuit board to receive a power signal from the circuit board, and a second electrode of the first electrical connection structure is electrically connected with a first electrode pin of the light-emitting device to provide the power signal to the light-emitting device, and the power signal is an electrical signal for driving the light-emitting device to emit light; the light-emitting substrate comprises a first conductive layer and a second conductive layer, the first conductive layer comprises the first electrode, and the second conductive layer comprises the second electrode; the light-emitting substrate further comprises a driving circuit, and the driving circuit is at least partially located in the light-emitting region; the second conductive layer further comprises a connection electrode, a first end of the connection electrode is electrically connected with the driving circuit, and a second end of the connection electrode is electrically connected with a second electrode pin of the light-emitting device to provide a light-emitting driving signal for the light-emitting device, and the light-emitting device emits light driven by the power signal and the light-emitting driving signal.

For example, in the light-emitting substrate provided by at least one embodiment of the present disclosure, the inorganic insulation layer includes a first sub-portion and a second sub-portion arranged in the vertical direction, and the second sub-portion is located at a side of the first sub-portion away from the base substrate; the first sub-portion has a first slope surrounding the first via hole, and the second sub-portion has a second slope surrounding the first via hole; the first electrode has a cover portion which is not exposed by the first via hole, the cover portion of the first electrode has an upper surface away from the base substrate, a first included angle is between the surface where the first slope is located and the upper surface of the cover portion, and a second included angle is between the surface where the second slope is located and the upper surface of the cover portion, and the second included angle is greater than the first included angle; the second sub-inorganic insulation layer comprises an upper portion and a lower portion, the lower portion is in contact with the first sub-inorganic insulation layer, the upper portion is located on the side of the lower portion away from the first sub-inorganic insulation layer, the upper portion serves as the second sub-portion, and a whole structure constituted by the lower portion and the first sub-inorganic insulation layer serves as the first sub-portion.

For example, in the light-emitting substrate provided by at least one embodiment of the present disclosure, the warpage level of the base substrate is less than 0.1 mm.

For example, in the light-emitting substrate provided by at least one embodiment of the present disclosure, the light-emitting substrate includes a plurality of the electrical connection structures, and the plurality of the electrical connection structures further includes a second electrical connection structure, the second electrical connection structure includes the first electrode of the electrical connection structure and the second electrode of the electrical connection structure; the light-emitting substrate further comprises a driving circuit which is at least partially located in the light-emitting region, and the light-emitting substrate comprises a light-emitting array, the light-emitting array comprises a plurality of light-emitting units arranged in an array, each light-emitting unit comprises a plurality of light-emitting devices, and the driving circuit is arranged corresponding to each light-emitting unit to control the light-emitting conditions of the light-emitting devices of the light-emitting units; the plurality of light-emitting units of the light-emitting array comprise a first light-emitting unit and a second light-emitting unit located in the same column; the first electrode of the second electrical connection structure is electrically connected with the circuit board to receive a light-emitting control signal from the circuit board, and the second electrode of the second electrical connection structure is electrically connected with an input end of the driving circuit corresponding to the first light-emitting unit, the light-emitting control signal comprises a light-emitting driving signal for controlling the light-emitting state of the light-emitting device and/or a timing control signal for controlling the light-emitting device to emit light; the plurality of electrical connection structures further include a third electrical connection structure, and the third electrical connection structure comprises the first electrode and the second electrode of the electrical connection structure; the second electrode of the third connection structure is electrically connected to an output terminal of the driving circuit corresponding to the first light-emitting unit, and the first electrode of the third electrical connection structure is electrically connected to an input terminal of the driving circuit corresponding to the second light-emitting unit to provide the light-emitting control signal to the second light-emitting unit.

For example, in the light-emitting substrate provided by at least one embodiment of the present disclosure, the plurality of electrical connection structures further comprise a fourth electrical connection structure, the fourth electrical connection structure includes the first electrode and the second electrode of the electrical connection structure; the first electrode of the fourth electrical connection structure is grounded, and the second electrode of the fourth electrical connection structure is electrically connected with a ground signal input terminal of the driving circuit.

For example, in the light-emitting substrate provided by at least one embodiment of the present disclosure, the light-emitting device is a mini light-emitting diode or a micro light-emitting diode.

At least one embodiment of the present disclosure further provides a display device, and the display device includes any one of the light-emitting substrates provided by the embodiments of the present disclosure. The light-emitting substrate is a display substrate, the light-emitting region is a display region and includes a sub-pixel, and the sub-pixel includes the light-emitting device; the electrical signal provided by the first electrode and the second electrode of the first electrical connection structure for driving the light-emitting device to emit light is a display driving signal to drive the light-emitting device to display images; or, the light-emitting substrate serves as a backlight of the display device and is configured to provide the display substrate with light for display.

At least one embodiment of the present disclosure provides a method for manufacturing a light-emitting substrate, which comprises: providing a base substrate, in which the base substrate has a main surface and includes a light-emitting region and a non-light-emitting region at least partially surrounding the light-emitting region; providing a light-emitting device on the main surface of the substrate, in which the light-emitting device is located in the light-emitting region; and forming an electrical connection structure on the main surface of the substrate, which comprises: forming a first electrode, in which the first electrode is located on the main surface of the substrate; forming an inorganic insulation layer, in which the inorganic insulation layer is stacked with the first electrode in a vertical direction perpendicular to the main surface of the base substrate, and is located at a side of the first electrode away from the main surface of the base substrate, the first electrode has an upper surface away from the base substrate, the inorganic insulation layer covers the upper surface of the first electrode, and the inorganic insulation layer is directly and tightly attached to the upper surface of the first electrode.

For example, in the manufacturing method of a light-emitting substrate provided by at least one embodiment of the present disclosure, the inorganic insulation layer is formed by a method of chemical vapor deposition.

### BRIEF DESCRIPTION OF DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 is a schematic structural diagram of a part of a light-emitting substrate where film layer breakage is prone to occur;

FIG. 2 is a FIB (Focused Ion Beam) sectional view of a part of a light-emitting substrate where film layer breakage is prone to occur;

FIG. 3 is a microscope diagram of a part of a light-emitting substrate where bubbling occurs;

FIG. 4 is a TEM (Transmission Electron Microscopy) sectional view of a part of a light-emitting substrate where bubbling occurs;

FIG. 5 is a schematic diagram of the overall structure of a light-emitting substrate provided by one embodiment of the present disclosure;

FIG. 6 is a schematic plan view of an electrical connection structure of a light-emitting substrate provided by one embodiment of the present disclosure;

FIG. 7 is a schematic cross-sectional view along line A1-A2 in FIG. 6;

FIG. 8 is another schematic cross-sectional view along line A1-A2 in FIG. 6;

FIG. 9A is a schematic diagram of an electrical connection structure of a display substrate provided in a light-emitting region and a non-light-emitting region provided by one embodiment of the present disclosure;

FIG. 9B is a schematic diagram of a display device provided by at least one embodiment of the present disclosure;

FIG. 10A-FIG. 10D are schematic diagrams of a method for manufacturing a light-emitting substrate provided by one embodiment of the present disclosure;

FIG. 11A-FIG. 11C are schematic diagrams of another method for manufacturing a light-emitting substrate provided by one embodiment of the present disclosure;

FIG. 12A-FIG. 12F are examples of products obtained by using different first oxygen concentrations and second oxygen concentrations according to the present disclosure;

FIG. 13 is a schematic diagram of a conductive structure of a light-emitting substrate in which there is a slit between a metal electrode and an inorganic layer.

FIG. 14 is a schematic plan view of a partial slice of a conductive structure of a light-emitting substrate where bubbling occurs;

FIG. 15 is a slice cross-sectional view of a section of the bubbling position within the dashed circle in FIG. 14;

FIG. 16 is an enlarged view of the position of the dashed circle in FIG. 15;

FIG. 17 is a scanning electron microscope (SEM) cross-sectional view of an electrical connection structure of a light-emitting substrate provided by one embodiment of the present disclosure;

FIG. 18 is a scanning electron microscope (SEM) cross-sectional view of another electrical connection structure of a light-emitting substrate provided by one embodiment of the present disclosure;

FIG. 19 is a scanning electron microscope (SEM) cross-sectional view of yet another electrical connection structure of a light-emitting substrate provided by one embodiment of the present disclosure;

FIG. 20 is a scanning electron microscope (SEM) cross-sectional view of yet another electrical connection structure of a light-emitting substrate provided by one embodiment of the present disclosure;

FIG. 21 is a scanning electron microscope (SEM) cross-sectional view of another electrical connection structure of a light-emitting substrate provided by one embodiment of the present disclosure; and

FIG. 22-FIG. 23 are scanning electron microscope (SEM) cross-sectional views of electrical connection structures with different film layer parameters provided by one embodiment of the present disclosure.

### DETAILED DESCRIPTION

In order to make objects, technical details and advantages of the embodiments of the disclosure apparent, the technical solutions of the embodiments will be described in a clear and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. Also, the terms “comprise,” “comprising,” “comprise,” “comprising,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may comprise an electrical connection, directly or indirectly. “On,” “under,” “left,” “right” and the like are only used to indicate relative position relationship, and when the position of the object which is described is changed, the relative position relationship may be changed accordingly.

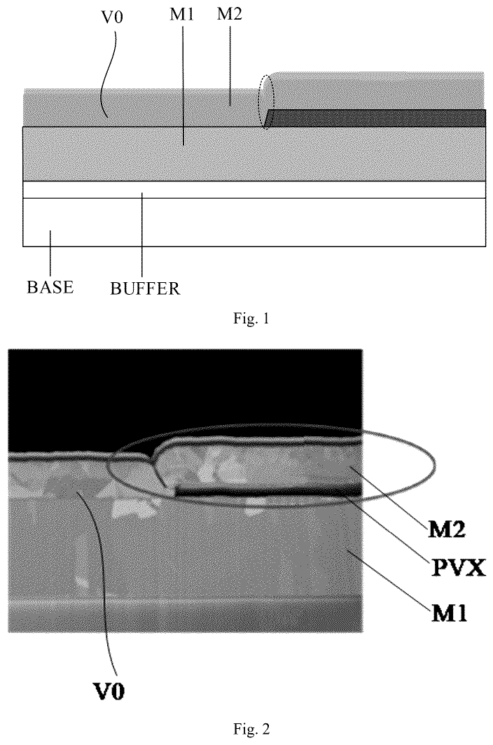

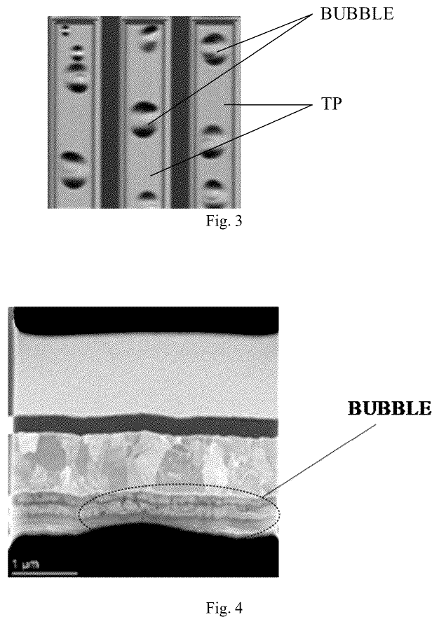

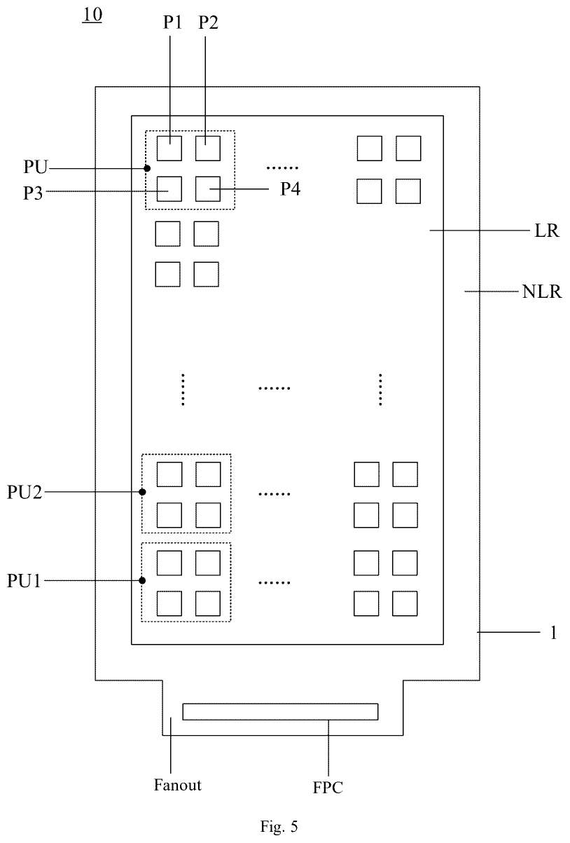

FIG. 1 is a schematic structural diagram of a part of a light-emitting substrate where film layer breakage is prone to occur; FIG. 2 is a FIB (Focused Ion Beam) sectional view of a part of a light-emitting substrate where film layer breakage is prone to occur; FIG. 3 is a microscope diagram of a part of a light-emitting substrate where bubbling occurs; and FIG. 4 is a TEM (Transmission Electron Microscopy) sectional view of a part of a light-emitting substrate where bubbling occurs. In a miniaturized light-emitting diode (LED) light-emitting substrate, in the case of using double metal layers to electrically connect with LEDs to provide a light-emitting signal to LEDs, referring to FIG. 1 and FIG. 2, a buffer layer BUFFER is provided on a base BASE, and double metal layers, LEDs, a circuit board FPC, respective interlayer insulation layers and various signal lines are provided on the buffer layer BUFFER. A first metal layer M1 in the double metal layers is electrically connected to the circuit board FPC in a bonding region, and a second metal layer M2 in the double metal layers is overlapped and in contact with the first metal layer M1 through a via hole V0 to be electrically connected to the first metal layer M1. Usually, it is necessary to form an insulation layer PVX with the via hole V0 by dry etching at least one insulation material layer, and then form the second metal layer M2.

The inventor(s) of the present disclosure discovered in the research that the side wall of the via hole V0 formed by dry etching the insulation material layer has a slope, and the second metal layer M2 will cover the slope. If the oxygen content in the dry etching gas used for dry etching the insulation material layer is relatively low, the slope angle of the slope will be larger, even reaching about 80°, which will make the second metal layer M2 prone to breakage at the slope, thereby causing electrical defects and reliability risks. The position illustrated by the dashed circle in FIG. 1 is a schematic diagram of a slope of the second metal layer M2 where breakage is prone to occur. The elliptical circle in FIG. 2 contains the slope of the second metal layer M2 where breakage is prone to occur. It can be seen from FIG. 2 that the second metal layer M2 has cracks at the slope. The black line in the elliptical circle in FIG. 2 is the cracked second metal layer M2, and the risk of the second metal layer M2 breaking is high. Furthermore, if the oxygen content in the dry etching gas used for dry etching the insulation material layer is relatively high, the slope angle of the slope of the side wall of the via hole V0 will be smaller, which is beneficial to reducing the risk of the second metal layer M2 breaking at the slope. However, after the insulation material layer is fully etched through, the first metal layer M1 at the via hole V0 will be exposed. After the exposed first metal layer MI is attacked by a high-oxygen atmosphere, the surface of the exposed first metal layer MI will be oxidized, which will lead to poor adhesion at the overlap between the first metal layer M1 and the second metal layer M2. This poor adhesion may result in bubbling defects, i.e., separation of the second metal layer M2 from the first metal layer M1, during subsequent high-temperature processes (such as OC OVEN or reflow soldering) or in high-temperature and high-humidity reliability environments, as illustrated in FIG. 3. In FIG. 3, the strip portion indicated by TP is the position where the second metal layer M2 overlaps with and is in contact with the first metal layer M1. There is a bubbling portion BUBBLE at the overlapping position, that is, bubbling occurs between the second metal layer M2 and the first metal layer M1. For example, the bubbling portion may include air bubbles and may also include other impurities, that is, the parts where the two layers are separated from each other.

Therefore, how to reduce the risk of the second metal layer M2 breaking at the slope of the side wall of the via hole V0 while preventing poor bubbling between the first metal layer M1 and the second metal layer M2 is a difficult problem. It is also of great significance to improve the reliability of the overlap between the first metal layer M1 and the second metal layer M2 through the via hole V0, so as to improve the reliability of the light-emitting signal provided to LEDs through the first metal layer M1 and the second metal layer M2 and ensure the production yield of the light-emitting substrate.

At least one embodiment of the present disclosure provides a light-emitting substrate, which includes a base substrate, a light-emitting device, and an electrical connection structure. The base substrate has a main surface, and includes a light-emitting region and a non-light-emitting region at least partially surrounding the light-emitting region; the light-emitting device is provided on the main surface of the base substrate and in the light-emitting region; and the electrical connection structure includes a first electrode, an inorganic insulation layer, and a second electrode. The first electrode is on the main surface of the base substrate; the inorganic insulation layer is stacked with the first electrode in a vertical direction perpendicular to the main surface of the base substrate, and is on a side of the first electrode away from the main surface of the base substrate, and the inorganic insulation layer includes a first via hole exposing the first electrode; the second electrode is stacked with the first electrode and the inorganic insulation layer in the vertical direction, is on a side of the inorganic insulation layer away from the first electrode, and is electrically connected to the first electrode through the first via hole; the inorganic insulation layer includes a first sub-portion and a second sub-portion that are arranged in the vertical direction, and the second sub-portion is on a side of the first sub-portion away from the base substrate; the first sub-portion includes a first slope surface surrounding the first via hole, and the second sub-portion includes a second slope surface surrounding the first via hole; and the first electrode includes a cover portion not exposed by the first via hole, the cover portion of the first electrode includes an upper surface away from the base substrate, a first included angle is formed between a surface where the first slope surface is located and the upper surface of the cover portion, a second included angle is formed between a surface where the second slope surface is located and the upper surface of the cover portion, and the second included angle is greater than the first included angle.

For example, the electrical connection structure includes a first electrical connection structure, the first electrical connection structure includes the first electrode and the second electrode, and the first electrode and the second electrode of the first electrical connection structure are configured to provide an electrical signal to the light-emitting device for driving the light-emitting device to emit light.

At least one embodiment of the present disclosure provides a method for manufacturing a light-emitting substrate, which includes: providing a base substrate, in which the base substrate has a main surface, and includes a light-emitting region and a non-light-emitting region at least partially surrounding the light-emitting region; providing a light-emitting device on the main surface of the base substrate, in which the light-emitting device is in the light-emitting region; and forming an electrical connection structure on the main surface of the base substrate. Forming an electrical connection structure on the main surface of the base substrate includes: forming a first electrode on the main surface of the base substrate; forming an inorganic insulation layer, in which the inorganic insulation layer is stacked with the first electrode in a vertical direction perpendicular to the main surface of the base substrate, and is on a side of the first electrode away from the main surface of the base substrate; forming a first via hole penetrating through the inorganic insulation layer, in which the first via hole exposes the first electrode; and forming a second electrode, in which the second electrode is stacked with the first electrode and the inorganic insulation layer in the vertical direction and is on a side of the inorganic insulation layer away from the first electrode, and is electrically connected to the first electrode through the first via hole. The inorganic insulation layer includes a first sub-portion and a second sub-portion that are arranged in the vertical direction, and the second sub-portion is on a side of the first sub-portion away from the base substrate; the first sub-portion includes a first slope surface surrounding the first via hole, and the second sub-portion includes a second slope surface surrounding the first via hole; the first electrode includes a cover portion not exposed by the first via hole, the cover portion of the first electrode includes an upper surface away from the base substrate, a first included angle is formed between a surface where the first slope surface is located and the upper surface of the cover portion, a second included angle is formed between a surface where the second slope surface is located and the upper surface of the cover portion, and the second included angle is greater than the first included angle. Forming the inorganic insulation layer includes forming an inorganic material layer, and performing dry etching on the inorganic material layer; and the dry etching includes: in a first dry etching stage, performing dry etching on the inorganic material layer under a first oxygen concentration condition; and in a second dry etching stage after the first dry etching stage, continuing to perform dry etching on the inorganic material layer after the first dry etching stage under a second oxygen concentration condition, in which gases used in both the first dry etching stage and the second dry etching stage include oxygen, an oxygen concentration of the gas used in the first dry etching stage is the first oxygen concentration, an oxygen concentration of the gas used in the second dry etching stage is the second oxygen concentration, and the first oxygen concentration is greater than the second oxygen concentration.

Exemplarily, FIG. 5 is a schematic diagram of the overall structure of a light-emitting substrate provided by one embodiment of the present disclosure. Referring to FIG. 5, the light-emitting substrate 10 provided by at least one embodiment of the present disclosure includes a base substrate 1, the base substrate 1 has a main surface, and the light-emitting substrate 10 includes a light-emitting region LR and a non-light-emitting region NLR at least partially surrounding the light-emitting region LR. Light-emitting units PUs are provided on the main surface of the base substrate 1, and the light-emitting units PUS are in the light-emitting region LR, and each includes a light-emitting device. For example, each light-emitting unit PU includes a plurality of sub-light-emitting units, for example, the light-emitting substrate 10 includes a plurality of light-emitting units PUs, and the plurality of light-emitting units PUs are arranged in an array. For example, in FIG. 5, one light-emitting unit PU includes four sub-light-emitting units, and the four sub-light-emitting units are respectively a first sub-light-emitting unit P1, a second sub-light-emitting unit P2, a third sub-light-emitting unit P3, and a fourth sub-light-emitting unit P4. Of course, the number of sub-light-emitting units is not limited to four, it may be fewer or more than four and may be designed according to specific requirements.

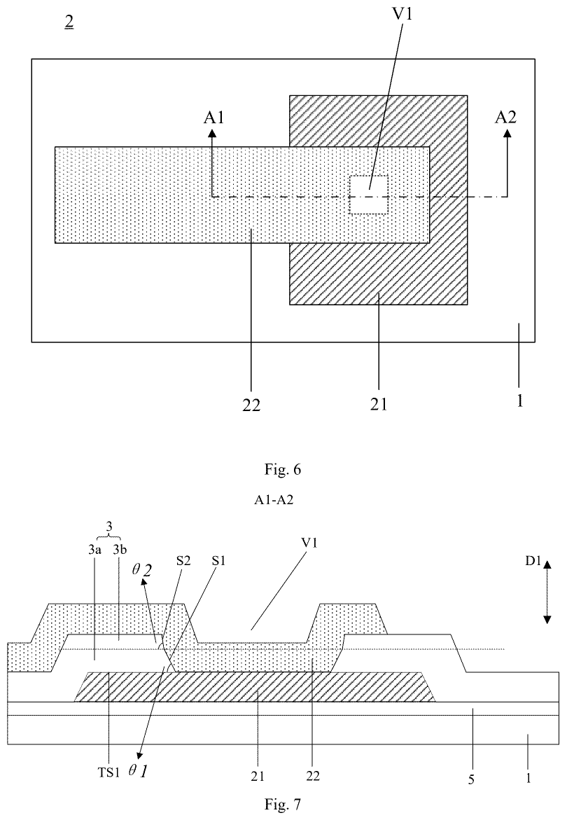

FIG. 6 is a schematic plan view of an electrical connection structure of a light-emitting substrate provided by one embodiment of the present disclosure; and FIG. 7 is a schematic cross-sectional view along line A1-A2 in FIG. 6. Referring to FIG. 5-FIG. 7, the light-emitting substrate 10 further includes an electrical connection structure 2 on the main surface of the base substrate 1. For example, the electrical connection structure 2 may be in the light-emitting region LR, or the electrical connection structure 2 may also be in the non-light-emitting region NLR. The electrical connection structure 2 includes a first electrode 21, an inorganic insulation layer 3, and a second electrode 22. The inorganic insulation layer 3 is stacked with the first electrode 21 in a vertical direction D1 perpendicular to the main surface of the base substrate 1, and is on a side of the first electrode 21 away from the main surface of the base substrate 1, and the inorganic insulation layer 3 includes a first via hole V1 exposing the first electrode 21. The second electrode 22 is stacked with the first electrode 21 and the inorganic insulation layer 3 in the vertical direction D1, is on a side of the inorganic insulation layer 3 away from the main surface of the first electrode 21, and is electrically connected to the first electrode 21 through the first via hole V1. The inorganic insulation layer 3 includes a first sub-portion 3a and a second sub-portion 3b that are arranged in the vertical direction D1, and the second sub-portion 3b is on a side of the first sub-portion 3a away from the base substrate 1; the first sub-portion 3a includes a first slope surface S1 surrounding the first via hole V1, and the second sub-portion 3b includes a second slope surface S2 surrounding the first via hole V1. The first electrode 21 includes a cover portion not exposed by the first via hole V1, and the cover portion of the first electrode 21 includes an upper surface TS1 away from the base substrate 1; a first included angle θ1 is formed between a surface where the first slope surface S1 is located and the upper surface TS1 of the cover portion, a second included angle θ2 is formed between a surface where the second slope surface S2 is located and the upper surface TS1 of the cover portion (represented by an included angle between a dashed line parallel to the upper surface TS1 of the cover portion and the surface where the second slope surface S2 is located in FIG. 7), and the second included angle θ2 is greater than the first included angle θ1, the first included angle θ1 is the slope angle of the first slope surface S1, and the second included angle θ2 is the slope angle of the second slope surface S2. Thus, the side wall of the inorganic insulation layer 3 surrounding the first via hole V1 (i.e., the hole wall of the first via hole V1) presents a double-step morphology, which prevents the slope angle of the entire side wall of the inorganic insulation layer 3 surrounding the first via hole V1 from being too large, thereby facilitating the adhesion of the second electrode 22 to the first slope surface S1 and the second slope surface S2, and avoiding the electrical and reliability defects caused by the breakage of the second electrode 22 at the hole wall of the first via hole V1. In addition, the double-step morphology may be manufactured by two dry etching processes, the first dry etching process uses an atmosphere with a high oxygen concentration, and the second dry etching process uses an atmosphere with a low oxygen concentration. Thus, not only can the double-step morphology structure be used to solve the problem that the second electrode 22 is easily broken at the position of the side wall of the inorganic insulation layer 3 surrounding the first via hole V1, but the two dry etching processes can also be used to avoid the problem that the first electrode 21 is over-oxidized under a high oxygen concentration after being exposed by the first via hole V0, thereby reducing the adhesion between the first electrode 21 and the second electrode, thereby solving the problem of poor bubbling between the second electrode 22 caused by the poor adhesion.

The second electrode 22 is continuous at the double step including the first slope surface S1 and the second slope surface S2, and covers the entire first via hole V0. The second electrode 22 has no break or crack, and no other impurities are mixed in the crack due to the crack.

For example, referring to FIG. 7, the thickness of the second sub-portion 3b in the vertical direction D1 is smaller than the thickness of the first sub-portion 3a in the vertical direction D1. In this way, the second sub-portion 3b corresponding to the second slope surface S2 having a larger slope angle has a smaller thickness, which facilitates the adhesion of the second electrode 22 to the first slope surface S1 and the second slope surface S2. Otherwise, even if the bubbling problem is solved, the adhesion effect between the second electrode 22 and the entire side wall (the entire slope surface) of the inorganic insulation layer 3 surrounding the first via hole V1 is not satisfactory, and the electrical and reliability defects caused by the breakage of the second electrode 22 at the hole wall of the first via hole V1 are further avoided.

For example, referring to FIG. 7, the ratio of the thickness of the second sub-portion 3b in the vertical direction D1 to the thickness of the inorganic insulation layer 3 in the vertical direction D1 is less than or equal to ⅓. After experimental verification, meeting this condition can achieve a better effect of preventing the second electrode 22 from breaking at the hole wall of the first via hole V1, thereby obtaining a higher electrical reliability.

For example, a buffer layer buffer is provided on the main surface of the base substrate 1, and the first electrode 21, the second electrode 22, the inorganic insulation layer 3, etc. are all provided on the buffer layer buffer.

For example, the first included angle θ1 is in the range of 15° to 30°, and the second included angle θ2 is in the range of 50° to 80°. The inventor(s) of the present application found that the size of the first included angle θ1 and the size of the second included angle θ2 have a great influence on preventing the second electrode from being broken. After experimental exploration, a relatively stable and good effect may be obtained within the above angle range. The second included angle θ2 cannot be too large, so as to facilitate the adhesion of the second electrode to the second slope surface forming the second included angle and prevent the second electrode from being broken. In addition, the size of the first included angle θ1 should not be too small or too large. If the first included angle θ1 is too small, for example, less than 15°, it will cause the first slope surface forming the first included angle to be difficult to manufacture. If the first included angle is too large, for example, greater than 30°, in the case where the above-mentioned two dry etching processes are used to manufacture the first slope surface and the second slope surface, the second included angle will be larger, which is not facilitate to the adhesion of the second electrode to the first slope surface, nor to the adhesion of the second electrode to the second slope surface, so that the second electrode is prone to breakage at the positions of the first slope surface and the second slope surface.

For example, referring to FIG. 7, a portion of the second electrode 22 in the first via hole V1 includes a lower surface and a side surface; the lower surface of the second electrode 22 is in contact with the first electrode 21 and there are no bubbles, gaps or impurities between the lower surface of the second electrode 22 and the first electrode 21; and the side surface of the second electrode 22 is in contact with the first slope surface S1 and the second slope surface S2 and there are no bubbles, gaps or impurities between the side surface of the second electrode 22 and the first slope surface S1 as well as the second slope surface S2. Here, “impurities” refer to substances other than the target layers of the first electrode 21, the second electrode 22 and the inorganic insulation layer 3 formed in the process.

As illustrated in FIG. 7, the portion of the second electrode 22 covering the first slope surface S1 and the second slope surface S2 away from the surface of the base substrate 1 includes a slope, and an included angle between the slope and the plane where the main surface of the base substrate 1 is located is the slope angle of the second electrode 22. For example, the slope angle of the second electrode 22 is less than 90°, for example, 30°-60°.

For example, the material of the inorganic insulation layer 3 includes at least one selected from a group consisting of silicon nitride, silicon oxide and silicon oxynitride. The materials of the first electrode 21 and the second electrode 22 are metal materials, and the metal materials include metals or alloys, for example, are both copper. Copper is a material with good conductivity, easy to obtain and manufacture, and is currently used in the electrical connection structure of the display substrate, so it is a preferred material. Alternatively, the materials of the first electrode 21 and the second electrode 22 may be manganese, chromium, copper alloy, manganese alloy, etc. However, the materials of the first electrode and the second electrode are not limited to the types listed above, and the embodiments of the present disclosure are not limited to this.

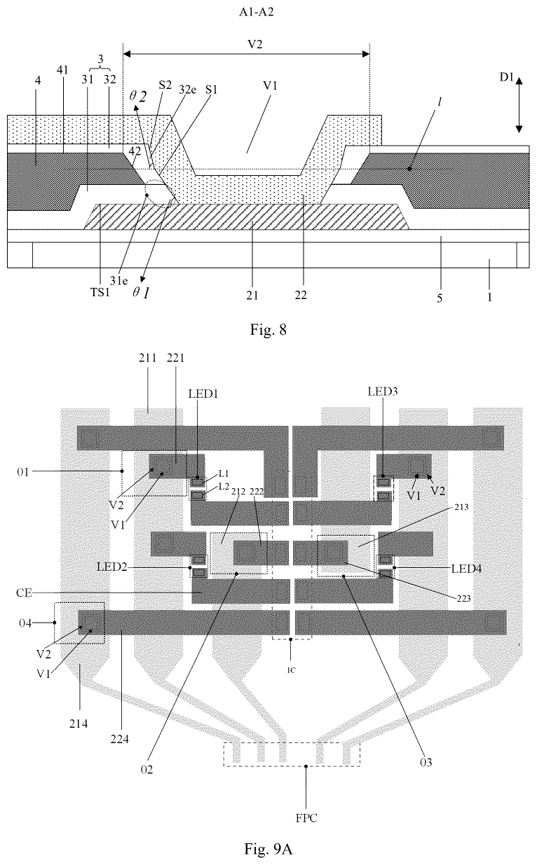

FIG. 8 is another schematic cross-sectional view along line A1-A2 in FIG. 6. The embodiment illustrated in FIG. 8 has the following differences from the embodiment illustrated in FIG. 7.

For example, referring to FIG. 8, for example, the inorganic insulation layer 3 includes a first sub-inorganic insulation layer 31 and a second sub-inorganic insulation layer 32 stacked on each other in the vertical direction D1, the second sub-inorganic insulation layer 32 is on a side of the first sub-inorganic insulation layer 31 away from the base substrate 1, and the first via hole V1 penetrates through the first sub-inorganic insulation layer 31 and the second sub-inorganic insulation layer 32; the second sub-inorganic insulation layer 32 includes an upper portion 32t and a lower portion 32b, the lower portion 32t is in contact with the first sub-inorganic insulation layer 31, the upper portion 32t is on a side of the lower portion 32b away from the first sub-inorganic insulation layer 31, the upper portion 32t serves as the second sub-portion including the second slope surface S2, and a whole structure constituted by the lower portion 32b and the first sub-inorganic insulation layer 31 serves as the first sub-portion including the first slope surface S1. The dashed line 1 in FIG. 8 is used as a schematic boundary between the upper portion 32t and the lower portion 32b. In the structure illustrated in FIG. 8, the inorganic insulation layer 3 is composed of two sub-inorganic insulation layers. The side wall (i.e., the hole wall of the first via hole V1) of the inorganic insulation layer 3 surrounding the first via hole V1 also presents a double-step morphology. Similar to the technical effect illustrated in FIG. 7, the embodiment illustrated in FIG. 8 may also prevent the slope angle of the entire side wall of the inorganic insulation layer 3 surrounding the first via hole V1 from being too large, thereby facilitating the adhesion of the second electrode 22 to the first slope surface S1 and the second slope surface S2, and avoiding the electrical and reliability defects caused by the breakage of the second electrode 22 at the hole wall of the first via hole V1. In addition, the double-step morphology may be manufactured by two dry etching processes. The first dry etching process uses an atmosphere with a high oxygen concentration, and the second dry etching process uses an atmosphere with a low oxygen concentration to solve the problem of poor bubbling between the second electrodes 22 caused by this.

For example, the material of the first sub-inorganic insulation layer 31 is the same as the material of the second sub-inorganic insulation layer 32. For example, the material of the first sub-inorganic insulation layer 31 and the material of the second sub-inorganic insulation layer 32 both include at least one selected from a group consisting of silicon nitride, silicon oxide and silicon oxynitride.

For example, referring to FIG. 8, the light-emitting substrate 10 further includes a first organic insulation layer 4, which is between the first sub-inorganic insulation layer 31 and the second sub-inorganic insulation layer 32, and includes a second via hole V2. The orthographic projection of the first via hole V1 on the base substrate 1 falls within the orthographic projection of the second via hole V2 on the base substrate 1. The first organic insulation layer 4 includes an upper surface 41 away from the base substrate 1 and a side surface 42 facing the first via hole V1. The second sub-inorganic insulation layer 32 covers the upper surface 41 and the side surface 42 of the first organic insulation layer 4. A portion of the first sub-inorganic insulation layer 31 close to the first via hole V1 includes a first edge portion 31e exposed by the second via hole V2, and a portion of the second sub-inorganic insulation layer 32 covering the side surface 42 of the first organic insulation layer 4 is a second edge portion 32e. The second edge portion 32e further covers the first edge portion 31e and is in contact with the first edge portion 31e. A whole structure constituted by the first edge portion 31e and the second edge portion 32e includes the first slope surface S1 and the second slope surface S2. Generally, after forming the first sub-inorganic insulation layer 31, the first organic insulation layer 4 is formed, and then the second sub-inorganic insulation layer 32 is formed. The second sub-inorganic insulation layer 32 covers the first organic insulation layer 4, and the second edge portion 32e of the second sub-inorganic insulation layer 32 wraps the edge of the first organic insulation layer 4, which can protect the first organic insulation layer 4 from being etched in the subsequent dry etching process of the inorganic insulation layer 3 composed of the first sub-inorganic insulation layer 31 and the second sub-inorganic insulation layer 32. The second electrode 22 is continuous at the double step including the first slope surface S1 and the second slope surface S2, the second electrode 22 covers the entire first via hole V0, and the second electrode 22 has no breakage, no cracks, and no other impurities are mixed in the cracks due to the cracks.

It should be noted that FIG. 8 is a cross-sectional view. In fact, the first edge portion 31e is in a ring shape surrounding the first via hole V1, for example, a ring shape closed around the entire first via hole V1.

For example, referring to FIG. 8, the first slope surface S1 includes the junction position of the first edge portion 31e and the second edge portion 32e, and the slope angle of the first slope surface S1 at the junction position is the same as the slope angle of the entire first slope surface S1. That is, the entire first slope surface S1 is a smooth transition, and there is no jump at the junction position, so as to facilitate the adhesion and continuity of the second electrode 22 on the first slope surface S1.

Other features illustrated in FIG. 8, such as the range of the first included angle θ1, the range of the second included angle θ2, the range of the slope angle of the second electrode 22, etc., and the corresponding technical effects are the same as those in the embodiment illustrated in FIG. 7, and the previous description can be referred to and will not be repeated here.

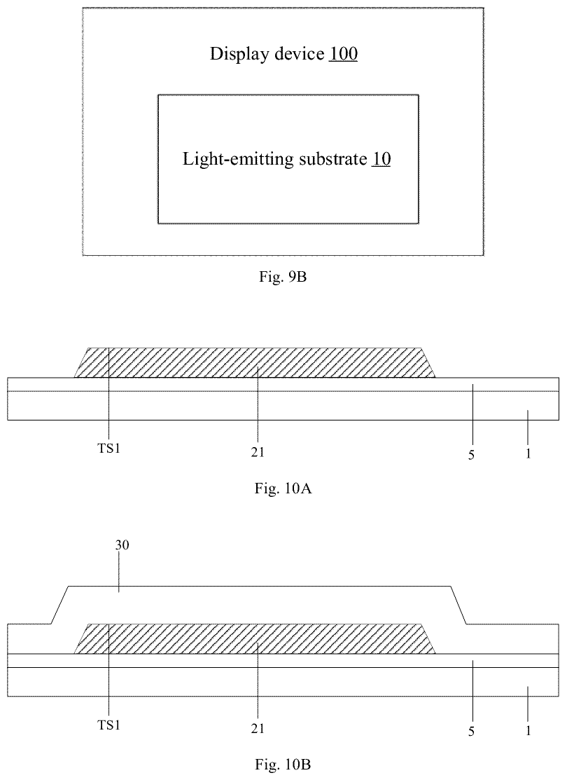

FIG. 9A is a schematic diagram of an electrical connection structure of a display substrate provided in a light-emitting region and a non-light-emitting region provided by one embodiment of the present disclosure. For example, a portion of the electrical connection structure is in the light-emitting region, and a portion of the electrical connection structure is in a fanout region Fanout of the non-light-emitting region. The position of the fanout region Fanout is illustrated in FIG. 5, and the fanout region Fanout may be bent to a non-light-emitting side of the light-emitting substrate opposite to a light-emitting side. For any display substrate provided in the embodiments of the present disclosure, the electrical connection structure illustrated in FIG. 9A may be the electrical connection structure illustrated in FIG. 7 or FIG. 8.

Referring to FIG. 9A, for example, each light-emitting device that performs the light-emitting function includes a first electrode pin L1 and a second electrode pin L2. The first electrode pin L1 and the second electrode pin L2 of the light-emitting device are represented by the positions of two dashed boxes in FIG. 9A, but the specific structure of the light-emitting device is not illustrated. For example, the light-emitting device may be transferred to the positions of the first electrode pin L1 and the second electrode pin L2, for example, the light-emitting device may be transferred to the above-mentioned positions by flip-chip method. Referring to FIG. 5 and FIG. 9A, the light-emitting substrate 10 further includes a circuit board FPC in the non-light-emitting region NLR. For example, the circuit board FPC is a flexible circuit board, but is not limited to a flexible circuit board.

For example, the light-emitting substrate includes a plurality of electrical connection structures, each of which includes the above-mentioned first electrode 21 and second electrode 22, for example, having the structure illustrated in FIG. 7 or FIG. 8. Four electrical connection structures are introduced below, namely the first electrical connection structure, the second electrical connection structure 02, the third electrical connection structure 03 and the fourth electrical connection structure. The positions and specific connection structures of these electrical connection structures are different to achieve different functions. These four electrical connection structures play an important role in the light-emitting substrate provided by the present disclosure. The problem of the above-mentioned second electrode being easily broken at the first slope surface and the second slope surface at these positions and the bubbling problem have a fatal impact on whether the light-emitting substrate can emit light and display normally. Therefore, solving the above-mentioned problems at these positions has a direct and significant impact on improving the light-emitting quality and display quality of the light-emitting substrate. Of course, the types and positions of the electrical connection structures, the structures connected and the functions realized are not limited to these four types, as long as they have the structures illustrated in FIG. 7 or FIG. 8.

For example, the electrical connection structure 2 includes a first electrical connection structure 01, and the first electrical connection structure 01 includes a first electrode and a second electrode of the above-mentioned electrical connection structure. In order to distinguish from other electrical connection structures, in FIG. 9A, the first electrode of the first electrical connection structure 01 is marked as 211, and the second electrode of the first electrical connection structure 01 is marked as 221. The first electrode 211 and the second electrode 221 of the first electrical connection structure 01 are configured to provide an electrical signal to the light-emitting device for driving the light-emitting device to emit light.

FIG. 9A illustrates four light-emitting devices LED1, LED2, LED3 and LED4 of the first light-emitting unit PU1. For each light-emitting device, the connection mode of the first electrical connection structure 01 is the same. Here, the light-emitting device LED1 is taken as an example. The first electrode 211 of the first electrical connection structure 01 is electrically connected to the circuit board FPC to receive the power signal from the circuit board FPC. The second electrode 221 of the first electrical connection structure 01 is electrically connected to the first electrode pin L1 of the light-emitting device LED1 to provide the power signal to the light-emitting device LED1. The power signal is an electrical signal for driving the light-emitting device LED1 to emit light, and the light-emitting device LED1 emits light under the action of the power signal from the first electrode pin L1 and the light-emitting driving signal from the second electrode pin L2.

For example, the light-emitting substrate 10 includes a first conductive layer and a second conductive layer, the first conductive layer includes the first electrode of each electrical connection structure, and the second conductive layer includes the second electrode of each electrical connection structure. The light-emitting substrate 10 further includes a driving circuit IC, and the driving circuit IC is at least partially in the light-emitting region LR. The light-emitting substrate includes a light-emitting array, the light-emitting array includes a plurality of light-emitting units arranged in an array, each light-emitting unit includes a plurality of light-emitting devices, and a driving circuit IC is provided corresponding to each light-emitting unit, and the driving circuit IC is configured to provide a light-emitting control signal to the light-emitting device of the corresponding light-emitting unit to control the light-emitting state of the light-emitting device of the light-emitting unit.

The second conductive layer further includes a connection electrode CE, a first end of the connection electrode CE is electrically connected to the driving circuit IC, and a second end of the connection electrode CE is electrically connected to the second electrode pin L2 of the light-emitting device to provide a light-emitting driving signal to the light-emitting device, and the light-emitting device is driven by the power signal and the light-emitting driving signal to emit light. For example, the light-emitting substrate may be a backlight panel, which can be used as a backlight source of a display panel. Alternatively, the light-emitting substrate may also be a display substrate, and the light-emitting device emits light to perform the display function. For example, the light-emitting driving signal is used to control the light-emitting brightness of the light-emitting device. For example, in the display substrate, each light-emitting unit P is a pixel, each sub-light-emitting unit P1-P4 is a sub-pixel, each sub-pixel includes a light-emitting device, and the light-emitting driving signal is used to control the display grayscale of the sub-pixel where the light-emitting device is located.

For example, referring to FIG. 9A, the plurality of electrical connection structures further include a second electrical connection structure 02, and the second electrical connection structure 02 includes the first electrode and the second electrode of the above-mentioned electrical connection structure. In order to distinguish from other electrical connection structures, in FIG. 9A, the first electrode of the second electrical connection structure 02 is marked as 212, and the second electrode of the second electrical connection structure 021 is marked as 222. The plurality of light-emitting units of the light-emitting array include a first light-emitting unit PU1 and a second light-emitting unit PU2 arranged in the same column, FIG. 9A only illustrates the first light-emitting unit PU1 as an example, and the position of the second light-emitting unit PU2 relative to the first light-emitting unit PU1 may refer to FIG. 5. For example, the extension direction of each column is from the circuit board FPC to the display region, for example, from the fan out region Fanout to the display region.

For example, referring to FIG. 9A, the first electrode 212 of the second electrical connection structure 02 is electrically connected to the circuit board FPC to receive the light-emitting control signal from the circuit board FPC, and the second electrode 222 of the second electrical connection structure 02 is electrically connected to an input terminal of the driving circuit IC corresponding to the first light-emitting unit PU1. The light-emitting control signal may be a light-emitting driving signal for controlling the light-emitting state of the light-emitting device, and the light-emitting driving signal is used to control the light-emitting brightness of the light-emitting device, or in the case where the light-emitting unit is a display pixel, the light-emitting control signal may be a data signal for controlling the grayscale of the light-emitting brightness of the light-emitting device. Alternatively, the light-emitting control signal may be a timing control signal for controlling the light-emitting device to emit light.

For example, referring to FIG. 9A, the plurality of electrical connection structures further include a third electrical connection structure 03, and the third electrical connection structure 03 includes the first electrode and the second electrode of the above-mentioned electrical connection structure. In order to distinguish from other electrical connection structures, in FIG. 9A, the first electrode of the third electrical connection structure 03 is marked as 213, and the second electrode of the third electrical connection structure 03 is marked as 223. The second electrode 223 of the third electrical connection structure 03 is electrically connected to an output terminal of the driving circuit IC corresponding to the first light-emitting unit PU1, and the first electrode 213 of the third electrical connection structure 03 is electrically connected to the input terminal of the driving circuit IC corresponding to the second light-emitting unit PU2, to provide the light-emitting control signal to the second light-emitting unit PU2.

For example, referring to FIG. 9A, the plurality of electrical connection structures 2 further include a fourth electrical connection structure 04, and the fourth electrical connection structure 04 includes the first electrode and the second electrode of the above-mentioned electrical connection structure. In order to distinguish from other electrical connection structures, in FIG. 9A, the first electrode of the fourth electrical connection structure 04 is marked as 214, and the second electrode of the fourth electrical connection structure 04 is marked as 224. The first electrode 214 of the fourth electrical connection structure 04 is grounded, and the second electrode 224 of the fourth electrical connection structure 04 is electrically connected to a ground signal input terminal of the driving circuit IC.

For example, the light-emitting device is a mini light-emitting diode (referred to as Mini LED) or a micro light-emitting diode (referred to as Micro LED). For example, the size of the Mini LED is about 100-300 μm. The size of the Micro LED is less than 100 μm.

The light-emitting substrate 10 includes a light-emitting array, and the light-emitting array includes a plurality of light-emitting units arranged in an array, each light-emitting unit includes a plurality of first electrical connection structures 01 and a plurality of light-emitting devices. In a light-emitting unit, the driving circuit IC and the connection electrode CE are in the middle, and the light-emitting devices are on both sides.

FIG. 9B is a schematic diagram of a display device provided by at least one embodiment of the present disclosure. Referring to FIG. 9B, the display device 100 includes any one of the light-emitting substrates 10 provided by the embodiments of the present disclosure. For example, the light-emitting substrate 10 is a display substrate, the light-emitting region LR is a display region and includes a pixel array, the pixel array includes a plurality of sub-pixels arranged in an array, and each sub-pixel used for display includes the above-mentioned light-emitting device. The electrical signal provided to the light-emitting device by the first electrode 21 and the second electrode 22 of the first electrical connection structure 01, which drives the light-emitting device to emit light, is the display driving signal used to drive the light-emitting device to display images.

Alternatively, in a display device that requires a backlight source, the light-emitting substrate 10 may be served as a backlight source for the display device, and is configured to provide light for display to the display substrate. For example, the display device 100 is a liquid crystal display device, and the light-emitting substrate 10 may be served as a backlight source for the liquid crystal display device.

For example, the display device 100 includes a light-emitting array, and the light-emitting array includes a plurality of light-emitting devices 10 arranged in an array. For example, the display device may be: a display, a display panel, a television, electronic paper, a mobile phone, a tablet computer, a laptop computer, a digital photo frame, a navigator, or any other product or component with a display function. Of course, the display device is not limited to the types listed above.

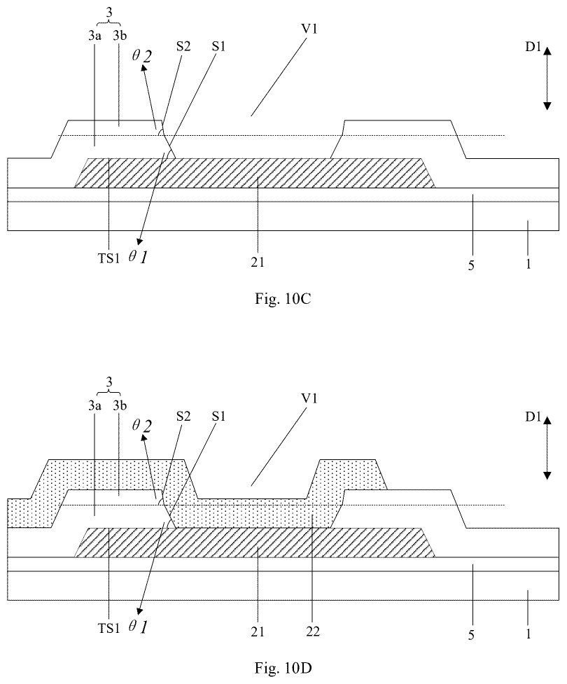

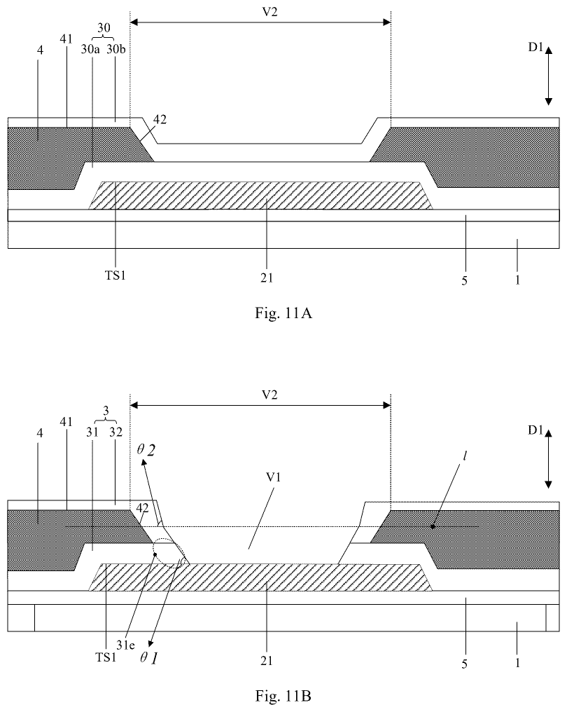

FIG. 10A-FIG. 10D are schematic diagrams of a method for manufacturing a light-emitting substrate provided by one embodiment of the present disclosure. Referring to FIG. 10A-FIG. 10D, the method for manufacturing the light-emitting substrate includes: providing a base substrate 1, in which the base substrate 1 has a main surface and includes a light-emitting region LR and a non-light-emitting region NLR at least partially surrounding the light-emitting region LR; providing a light-emitting device on the main surface of the base substrate 1, in which the light-emitting device is in the light-emitting region LR; and forming an electrical connection structure 2 on the main surface of the base substrate 1.

Specifically, a method for forming an electrical connection structure 2 provided by one embodiment of the present disclosure is introduced below in conjunction with FIG. 10A-FIG. 10D.

Referring to FIG. 10A, a base substrate 1 is provided, and the base substrate 1 has a main surface, and includes a light-emitting region LR and a non-light-emitting region NLR at least partially surrounding the light-emitting region LR. Forming the electrical connection structure 2 on the main surface of the base substrate 1 includes forming a first electrode 21 on the main surface of the base substrate 1. Before forming the first electrode 21, a buffer layer buffer is formed on the main surface of the base substrate 1, and the first electrode 21 is formed on the buffer layer buffer. For example, the first electrode 21 is formed by a patterning process. For example, the material of the first electrode 21 is a metal material, and the metal material includes a metal or an alloy, for example, copper. Copper is a material with good conductivity, easy to obtain and manufacture, which is currently used in the conductive connection structure of the display substrate, so it is a preferred material. Alternatively, the material of the first electrode 21 may be manganese, chromium, copper alloy, manganese alloy, etc. However, the materials of the first electrode and the second electrode are not limited to the types listed above, and the embodiments of the present disclosure are not limited to this.

Then, referring to FIG. 10B, forming the inorganic insulation layer 3 includes: forming an inorganic material layer 30, in which the inorganic insulation layer 3 is stacked with the first electrode 21 in the vertical direction D1 perpendicular to the main surface of the base substrate 1, and is on a side of the first electrode 21 away from the main surface of the base substrate 1, and the inorganic material layer 30 covers the first electrode 21; and performing dry etching on the inorganic material layer 30, the dry etching including: in a first dry etching stage, performing dry etching on the inorganic material layer under a first oxygen concentration condition; and in a second dry etching stage after the first dry etching stage, continuing to perform dry etching on the inorganic material layer 30 after the first dry etching stage under a second oxygen concentration condition. The gases used in both the first dry etching stage and the second dry etching stage include oxygen, and the oxygen concentrations of the gases used in the first dry etching stage and the second dry etching stage are different; the oxygen concentration of the gas used in the first dry etching stage is the first oxygen concentration, the oxygen concentration of the gas used in the second dry etching stage is the second oxygen concentration, and the first oxygen concentration is greater than the second oxygen concentration.

As illustrated in FIG. 10C, after sequentially undergoing the first dry etching stage and the second dry etching stage, a first via hole V1 penetrating through the inorganic insulation layer 3 is formed. The first via hole V1 exposes a portion of the first electrode 21. The inorganic insulation layer 3 is stacked with the first electrode 21 in the vertical direction D1 perpendicular to the main surface of the base substrate 1, and is on the side of the first electrode 21 away from the main surface of the base substrate 1. The inorganic insulation layer 3 includes a first sub-portion 3a and a second sub-portion 3b that are arranged in a vertical direction D1, and the second sub-portion 3b is on a side of the first sub-portion 3a away from the base substrate 1; the first sub-portion 3a includes a first slope surface S1 surrounding the first via hole V1, and the second sub-portion 3b includes a second slope surface S2 surrounding the first via hole V1; the first electrode 21 includes a cover portion not exposed by the first via hole V1, and the cover portion of the first electrode 21 includes an upper surface away from the base substrate 1, a first included angle θ1 is formed between a surface where the first slope surface S1 is located and the upper surface TS1 of the cover portion, a second included angle θ2 is formed between a surface where the second slope surface S2 is located and the upper surface TS1 of the cover portion, and the second included angle θ2 is greater than the first included angle θ1.

In the above-mentioned method, the first slope surface S1 having a smaller first slope angle θ1 is formed by the first dry etching stage under a high oxygen concentration gas atmosphere, and then the second slope surface S2 having a larger second slope angle θ2 is formed by the second dry etching stage under a low oxygen concentration gas atmosphere. The side wall (i.e., the hole wall of the first via hole V1) of the inorganic insulation layer 3 surrounding the first via hole V1 presents a double-step morphology.

Then, referring to FIG. 10D, a second electrode 22 is formed. The second electrode 22 is stacked with the first electrode 21 and the inorganic insulation layer 3 in the vertical direction D1, and is on the side of the inorganic insulation layer 3 away from the main surface of the first electrode 21, and is electrically connected to the first electrode 21 through the first via hole V1. Thus, the electrical connection structure of the display substrate illustrated in FIG. 7 is obtained.

The second electrode 22 is continuous at the double step including the first slope surface S1 and the second slope surface S2, and the second electrode 22 covers the entire first via hole V0, and the second electrode 22 has no breakage, no cracks, and no other impurities are mixed in the cracks due to the cracks.

In this way, in the first dry etching stage, the oxygen concentration is high, and the dry etching gas etches the edge of the photoresist used in the etching process faster, so that the slope angle of the first slope surface S1 formed is smaller, which may prevent the slope angle of the entire side wall of the inorganic insulation layer 3 surrounding the first via hole V1 being too large, thereby facilitating the adhesion of the subsequently formed second electrode 22 to the entire slope surface. Moreover, in the second dry etching stage, the oxygen concentration is high. Although the slope angle formed is large, the proportion of the larger slope angle may be controlled to be smaller, thereby reducing the risk of the second electrode 22 breaking at the slope surface. In addition, the risk of the subsequently formed second electrode 22 breaking at the slope of the side wall of the first via V1 may be reduced. In addition, before entering the second dry etching stage, a part of the first electrode 21 has been exposed by the first via hole V1 or is about to be exposed by the first via hole V1. Therefore, the second dry etching stage adopts a gas atmosphere with a low oxygen concentration, which may avoid the problem that the first electrode 21 is over-oxidized under a high oxygen concentration after being exposed by the first via hole V0, thereby reducing the adhesion between the first electrode 21 and the second electrode, thereby solving the problem of poor bubbling between the second electrode 22 caused by the poor adhesion, and thereby preventing the electrical and reliability defects caused by the breakage of the second electrode 22.

For example, the duration of the second dry etching stage is shorter than the duration of the first dry etching stage, so that the thickness of the second sub-portion 3b in the vertical direction D1 is smaller than the thickness of the first sub-portion 3a in the vertical direction D1. In this way, the second sub-portion 3b corresponding to the second slope surface S2 with a larger slope angle has a smaller thickness, which facilitates the adhesion of the second electrode 22 to the first slope surface S1 and the second slope surface S2. Otherwise, even if the above-mentioned bubbling problem is solved, the adhesion effect between the second electrode 22 and the entire side wall (the entire slope surface) of the inorganic insulation layer 3 surrounding the first via hole V1 is not satisfactory, and further better avoids the electrical and reliability defects caused by the second electrode 22 being broken at the hole wall of the first via hole V1.

For example, the electrical connection structure 2 of the display substrate 10 includes a first electrical connection structure 01, the first electrical connection structure 01 includes a first electrode 21 and a second electrode 22, and the first electrode 21 and the second electrode 22 of the first electrical connection structure 01 are configured to provide an electrical signal to the light-emitting device for driving the light-emitting device to emit light.

For example, the electrical connection structure of the display substrate 10 may also include the second electrical connection structure, the third electrical connection structure and the fourth electrical connection structure in the embodiment of the above-mentioned display substrate 10.

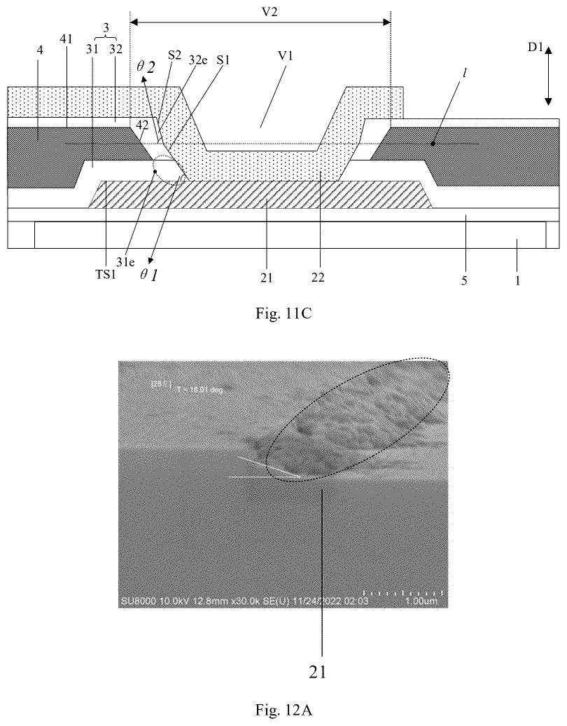

FIG. 11A-FIG. 11C are schematic diagrams of another method for manufacturing a light-emitting substrate provided by one embodiment of the present disclosure. The embodiment illustrated in FIG. 11A-FIG. 11C has the following differences from the embodiment illustrated in FIG. 10A-FIG. 10D.

Referring to FIG. 11A, forming the inorganic insulation layer 3 includes forming a first sub-inorganic material layer 30a after forming the first electrode 21. The first sub-inorganic material layer 30a covers the first electrode 21. Forming the inorganic insulation layer 3 further includes forming a first organic insulation layer, and forming a second via hole V2 penetrating through the first organic insulation layer. The orthographic projection of the first via hole V1 on the base substrate 1 falls within the orthographic projection of the second via hole V2 on the base substrate 1, and the first organic insulation layer 4 includes an upper surface 41 away from the base substrate 1 and a side surface 42 facing the first via hole V1.

For example, referring to FIG. 11 A, forming the inorganic insulation layer 3 further includes forming a second sub-inorganic material layer 30b. The second sub-inorganic material layer 30b is stacked and in contact with the first sub-inorganic material layer 30a in the vertical direction D1, and a whole structure constituted by the first sub-inorganic material layer 30a and the second sub-inorganic material layer 30b serves as the above-mentioned inorganic material layer.

Referring to FIG. 11B, forming the electrical connection structure includes performing dry etching on the inorganic material layer composed of the first sub-inorganic material layer 30a and the second sub-inorganic material layer 30b, and the dry etching includes a first dry etching stage and a second dry etching stage. In the first dry etching stage, the dry etching is performed on the inorganic material layer under a first oxygen concentration; and in the second dry etching stage after the first dry etching stage, the dry etching is continued to be performed on the inorganic material layer 30 after the first dry etching stage under a second oxygen concentration. The gases used in both the first dry etching stage and the second dry etching stage include oxygen, and the oxygen concentration of the gas used in the first dry etching stage is different from the oxygen concentration of the gas used in the second dry etching stage. The oxygen concentration of the gas used in the first dry etching stage is a first oxygen concentration, and the oxygen concentration of the gas used in the second dry etching stage is a second oxygen concentration, and the first oxygen concentration is greater than the second oxygen concentration.

As illustrated in FIG. 11B, after sequentially undergoing the first dry etching stage and the second dry etching stage, a first via hole V1 penetrating through the inorganic insulation layer 3 is formed. The first via hole V1 exposes a portion of the first electrode 21. The inorganic insulation layer 3 is stacked with the first electrode 21 in the vertical direction D1 perpendicular to the main surface of the base substrate 1, and is on a side of the first electrode 21 away from the main surface of the base substrate 1. The inorganic insulation layer 3 includes a first sub-portion 3a and a second sub-portion 3b that are arranged in the vertical direction D1, and the second sub-portion 3b is on a side of the first sub-portion 3a away from the base substrate 1; the first sub-portion 3a includes a first slope surface S1 surrounding the first via hole V1, and the second sub-portion 3b includes a second slope surface S2 surrounding the first via hole V1; the first electrode 21 includes a cover portion not exposed by the first via hole V1, and the cover portion of the first electrode 21 includes an upper surface away from the base substrate 1; and a first included angle θ1 is formed between a surface where the first slope surface S1 is located and the upper surface TS1 of the cover portion, a second included angle θ2 is formed between a surface where the second slope S2 is located and the upper surface TS1 of the cover portion, and the second included angle θ2 is greater than the first included angle θ1.

In the above-mentioned method, the first slope surface S1 having a smaller first slope angle θ1 is formed by the first dry etching stage under a high oxygen concentration gas atmosphere, and then the second slope surface S2 having a larger second slope angle θ2 is formed by the second dry etching stage under a low oxygen concentration gas atmosphere. The side wall (i.e., the hole wall of the first via hole V1) of the inorganic insulation layer 3 surrounding the first via hole V1 presents a double-step morphology.

Then, referring to FIG. 10D, a second electrode 22 is formed. The second electrode 22 is stacked with the first electrode 21 and the inorganic insulation layer 3 in the vertical direction D1, and is on the side of the inorganic insulation layer 3 away from the main surface of the first electrode 21, and is electrically connected to the first electrode 21 through the first via hole V1. Thus, the electrical connection structure of the display substrate illustrated in FIG. 8 is obtained.

For example, the duration of the second dry etching stage is shorter than the duration of the first dry etching stage, so that the thickness of the second sub-portion in the vertical direction D1 is smaller than the thickness of the first sub-portion in the vertical direction D1. In this embodiment, for the division of the first sub-portion and the second sub-portion, please refer to the description of the embodiment illustrated in FIG. 8. In this way, the second sub-portion corresponding to the second slope surface S2 with a larger slope angle has a smaller thickness, which facilitates the adhesion of the second electrode 22 to the first slope surface S1 and the second slope surface S2. Otherwise, even if the above-mentioned bubbling problem is solved, the adhesion effect between the second electrode 22 and the entire side wall (the entire slope surface) of the inorganic insulation layer 3 surrounding the first via hole V1 is not satisfactory, and further better avoids the electrical and reliability defects caused by the second electrode 22 being broken at the hole wall of the first via hole V1.

For example, at the end of the first dry etching stage, the upper surface of the first electrode 21 has not been exposed. At this time, the second dry etching stage is entered to ensure that the upper surface of the first electrode 21 does not contact the gas environment with a high oxygen concentration, so as to avoid the problem of bubbling due to the decrease in adhesion of the upper surface of the first electrode 21.

Alternatively, for example, at the end of the first dry etching stage, the upper surface of the first electrode 21 is precisely just exposed. At this time, the second dry etching stage is entered to minimize the time that the upper surface of the first electrode 21 is exposed to the gas atmosphere with a high oxygen concentration, so as to avoid the problem of bubbling caused by the decrease in adhesion due to oxidation of the upper surface of the first electrode 21.

Here, “precisely just exposed” means that at the end of the first dry etching stage, the time for which the upper surface of the first electrode 21 is exposed may be very short, for example, less than 5% of the duration of the first dry etching stage or less than 10 s.

For example, in the first dry etching stage and the second dry etching stage, the gases used for dry etching include oxygen and an auxiliary gas, and the oxygen concentration is the ratio of oxygen to the total amount of oxygen and auxiliary gas; and the first oxygen concentration ranges from 60% to 80%, and the second oxygen concentration ranges from 8% to 25%. For example, the auxiliary gas is CF4, but of course it is not limited to CF4.

The following introduces several examples of products obtained by using different first oxygen concentrations and second oxygen concentrations.

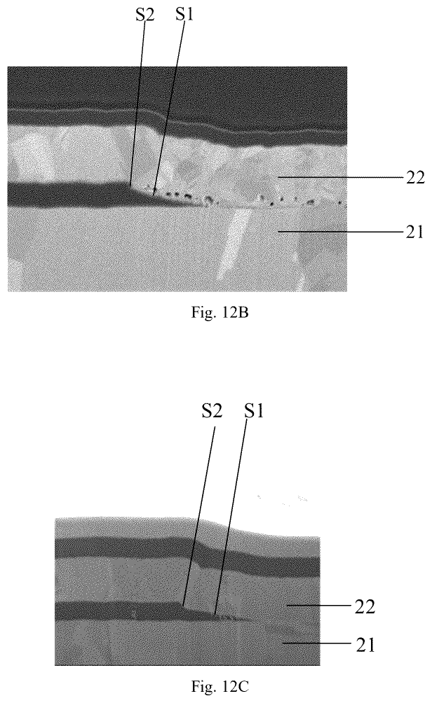

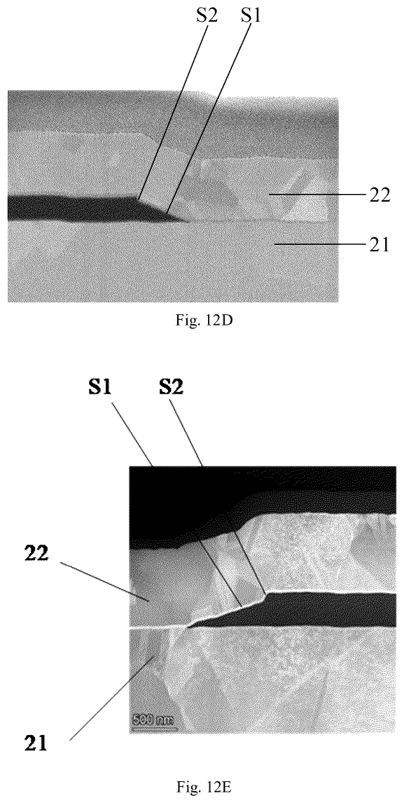

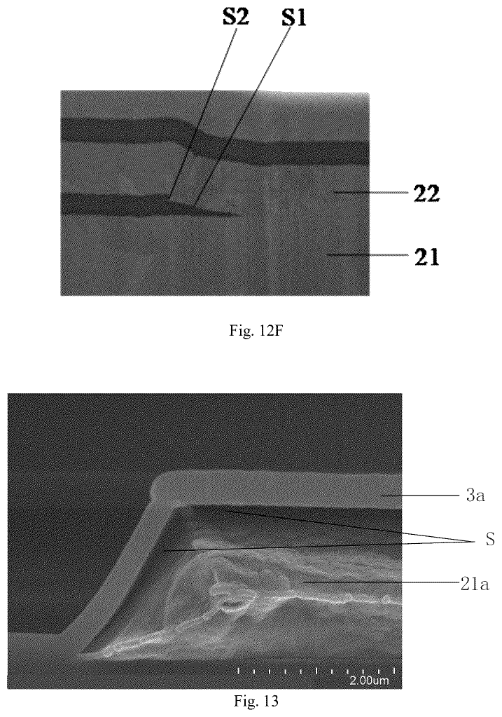

The first oxygen concentration adopted ranges from 60% to 80%, and the second oxygen concentration adopted in the second dry etching stage is 0%. The resulting electrical connection structure is illustrated in FIG. 12A (FIB sectional view). The electrical connection structure in the actual product can achieve the expected effect. The positions of the white lines in FIG. 12A are the positions of two slope surfaces, and the second electrode is not broken at the positions of the two slope surfaces. However, because the second oxygen concentration adopted in the second dry etching stage is 0%, the dry etching reaction products are difficult to remove, resulting in a large amount of dry etching byproducts remaining at the slope angle edge of the first slope surface.

The first oxygen concentration adopted in the first dry etching stage ranges from 60% to 80%, and the second oxygen concentration adopted in the second dry etching stage is 7%. The resulting electrical connection structure is illustrated in FIG. 12B. The electrical connection structure in the actual product can achieve the expected effect. The positions of the white lines in FIG. 12B are the positions of two slope surfaces, and the second electrode is not broken at the positions of the two slope surfaces. However, because the second oxygen concentration adopted in the second dry etching stage is low, the dry etching reaction products are difficult to remove, resulting in a small amount of dry etching byproducts remaining at the slope angle edge of the first slope surface and at the overlap of the second electrode and the first electrode (illustrated as holes in the FIB sectional view illustrated in FIG. 12B).

The first oxygen concentration adopted in the first dry etching stage is from 60% to 80%, and the second oxygen concentration adopted in the second dry etching stage is 8%. The resulting electrical connection structure is illustrated in FIG. 12C. The electrical connection structure in the actual product can achieve the expected effect. The positions of the white lines in FIG. 12C are the positions of the two slope surfaces, and the second electrode is not broken at the positions of the two slope surfaces. However, because the second oxygen concentration adopted in the second dry etching stage is low, the dry etching reaction products are difficult to completely remove, resulting in a smaller amount of dry etching byproducts remaining at the slope angle edge of the first slope and at the overlap of the second electrode and the first electrode (illustrated as holes in the FIB sectional view illustrated in FIG. 12C). After product testing, the impact on the product under this condition is small and can be applied.

The first oxygen concentration adopted in the first dry etching stage ranges from 60% to 80%, and the second oxygen concentration adopted in the second dry etching stage is 13%. The resulting electrical connection structure is illustrated in FIG. 12D (FIB sectional view) and FIG. 12E (TEM sectional view). The electrical connection structure in the actual product can achieve a more ideal effect. The positions of the white lines in the figures are the positions of two slope surfaces. The second electrode is not broken at the positions of the two slope surfaces. There are no dry etching by-products remaining on the slope angle edge of the first slope and the overlap between the second electrode and the first electrode. The second electrode and the first electrode also have an ideal bonding effect without bubbling.

The first oxygen concentration adopted in the first dry etching stage ranges from 60% to 80%, and the second oxygen concentration adopted in the second dry etching stage is 25%. The resulting electrical connection structure is illustrated in FIG. 12F. The electrical connection structure in the actual product can achieve the expected effect. The positions of the white lines in FIG. 2F are the positions of two slope surfaces, and the second electrode is not broken at the positions of the two slope surfaces. However, because the second oxygen concentration adopted in the second dry etching stage is low, the dry etching reaction products are difficult to completely remove, resulting in a smaller amount of dry etching byproducts remaining at the slope angle edge of the first slope and at the overlap of the second electrode and the first electrode (illustrated as holes in the FIB sectional view illustrated in FIG. 12F). After product testing, the impact on the product under this condition is small and can be applied.

In addition, after product analysis and testing, in the case where the second oxygen concentration adopted in the second dry etching stage is greater than 25%, the exposed first electrode is severely oxidized and the product bubbling phenomenon is serious.

Therefore, in the case where the first oxygen concentration adopted in the first dry etching stage ranges from 60% to 80%, and the second oxygen concentration adopted in the second dry etching stage is within the range of 8%≤O2≤25%, the actual product can achieve the expected effect, and no other related defects are obviously produced.

For example, after experimental exploration and product testing, the first step of PVX1 dry etching high oxygen atmosphere selects an oxygen content of about 74% (floating about 5%), and the second step of PVX1 dry etching low oxygen atmosphere selects an oxygen content of about 13% (floating about 5%), which may be the best embodiment.

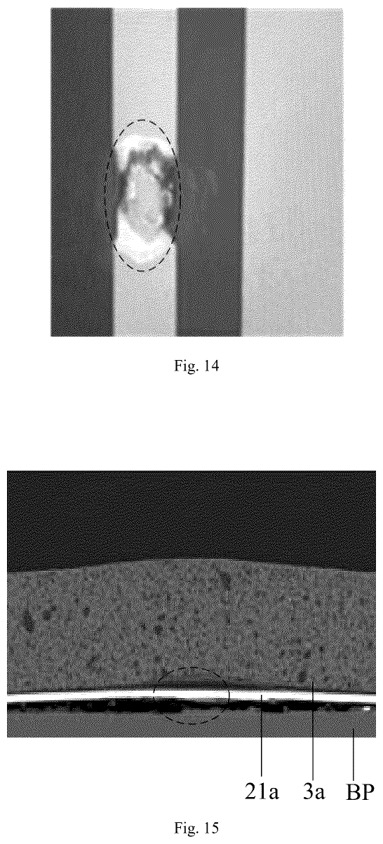

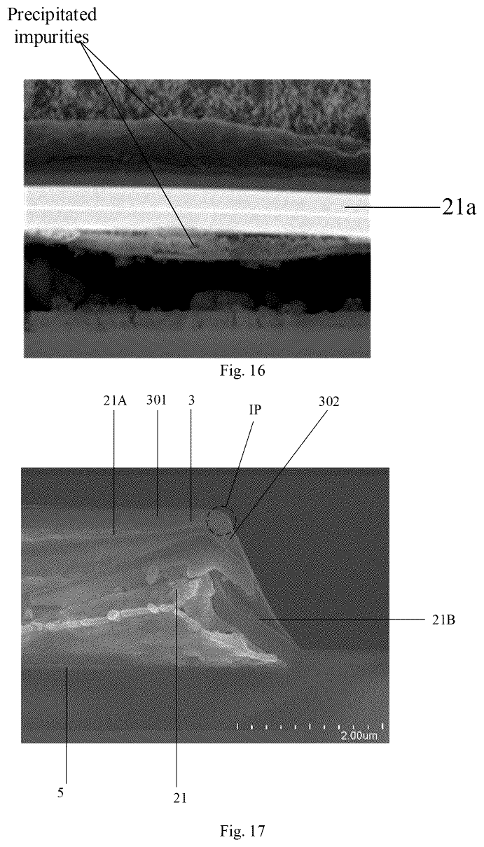

The following problems currently exist in MLED light-emitting substrates.
(1) For MLED light-emitting substrates, such as MLED light-emitting substrates using glass substrates, it is found that during the die bonding of the MLED, the glass substrate exhibited significant warping, failing to meet the warping specification (<0.2mm), so that die bonding Rework cannot be achieved, resulting in the product being unable to proceed with subsequent processes.
(2) FIG. 13 is a schematic diagram of a conductive structure of a light-emitting substrate in which there is a slit S (the black part is the slit S) between a metal electrode 21a and an inorganic layer 3a. In this case, the slit between the metal electrode and the inorganic layer causes the conductive structure to be unstable and poor in resistance to pressure and impact.
(3) FIG. 14 is a schematic plan view of a partial slice of a conductive structure of a light-emitting substrate where bubbling occurs; FIG. 15 is a slice cross-sectional view of a section of a bubbling position within the dashed circle in FIG. 14; and FIG. 16 is an enlarged view of the dashed circle position in FIG. 15. Referring to FIG. 14 to FIG. 16, in the case where SDL glass is adopted in current glass-based MLED products, the entire surface will corrode during reliability testing. The main reason is that during the environmental testing, the glass itself has Na/Ca ions that precipitate and grow abnormally, which causes corrosion of the conductive metal layer and bubbling defects, which seriously affects the reliability performance of the MLED light-emitting substrate.

At least one embodiment of the present disclosure provides a light-emitting substrate, which includes a base substrate, a light-emitting device, and an electrical connection structure. The substrate has a main surface, and the light-emitting substrate includes a light-emitting region and a non-light-emitting region at least partially surrounding the light-emitting region; the light-emitting device is provided on the main surface of the base substrate and in the light-emitting region; the electrical connection structure includes a first electrode and an inorganic insulation layer; the first electrode is on the main surface of the base substrate; the inorganic insulation layer is stacked with the first electrode in a vertical direction perpendicular to the main surface of the base substrate, and is on a side of the first electrode away from the main surface of the base substrate; the first electrode includes an upper surface away from the base substrate, the inorganic insulation layer covers the upper surface of the first electrode, and the inorganic insulation layer is directly and tightly attached to the upper surface of the first electrode. The light-emitting substrate provided by at least one embodiment of the present disclosure can increase the structural stability and mechanical strength of the electrical connection structure, improve the pressure resistance and impact resistance of the electrical connection structure, and is beneficial to increasing the service life of the light-emitting substrate.

At least one embodiment of the present disclosure further provides a display device, which includes any one of the light-emitting substrates provided in the embodiments of the present disclosure. The light-emitting substrate is a display substrate, the light-emitting region is a display region and includes sub-pixels, and the sub-pixels each include the light-emitting device; the electrical signal provided by the first electrode and the second electrode of the first electrical connection structure to the light-emitting device for driving the light-emitting device to emit light is a display driving signal to drive the light-emitting device to display images; or, the light-emitting substrate serves as a backlight source for the display device and is configured to provide light for display to the display substrate.

At least one embodiment of the present disclosure provides a method for manufacturing a light-emitting substrate, which includers: providing a base substrate, in which the base substrate has a main surface and includes a light-emitting region and a non-light-emitting region at least partially surrounding the light-emitting region; providing a light-emitting device on the main surface of the base substrate, in which the light-emitting device is in the light-emitting region; and forming an electrical connection structure on the main surface of the base substrate, which includes: forming a first electrode, in which the first electrode is on the main surface of the base substrate; forming an inorganic insulation layer, in which the inorganic insulation layer is stacked with the first electrode in a vertical direction perpendicular to the main surface of the base substrate, and is on a side of the first electrode away from the main surface of the base substrate; and the first electrode includes an upper surface away from the base substrate, and the inorganic insulation layer covers the upper surface of the first electrode; and there is a first slit between the inorganic insulation layer and the upper surface of the first electrode, and the width of the first slit is less than 0.2 μm.

Exemplarily, FIG. 5 is a schematic diagram of the overall structure of a light-emitting substrate provided by one embodiment of the present disclosure. The light-emitting substrate 10 provided by at least one embodiment of the present disclosure includes a light-emitting region LR and a non-light-emitting region NLR at least partially surrounding the light-emitting region LR. A light-emitting unit PU is provided on the main surface of the base substrate 1, and the light-emitting unit PU is in the light-emitting region LR and includes a light-emitting device. For example, each light-emitting unit PU includes a plurality of sub-light-emitting units, for example, the light-emitting substrate 10 includes a plurality of light-emitting units PUs, and the plurality of light-emitting units PUs are arranged in an array. For example, FIG. 5 takes one light-emitting unit PU including four sub-light-emitting units as an example, and the four sub-light-emitting units are a first sub-light-emitting unit P1, a second sub-light-emitting unit P2, a third sub-light-emitting unit P3, and a fourth sub-light-emitting unit P4. Of course, the number of sub-light-emitting units is not limited to four; and it may be fewer or more than four, and may be designed according to specific requirements.

FIG. 17 is a SEM (scanning electron microscope) cross-sectional view of an electrical connection structure of a light-emitting substrate provided by one embodiment of the present disclosure. Referring to FIG. 17, the light-emitting substrate 10 includes an electrical connection structure 2. The electrical connection structure 2 includes a first electrode 21 and an inorganic insulation layer 3; the first electrode 21 is on the main surface of the base substrate 1; the inorganic insulation layer 3 is stacked with the first electrode 21 in a vertical direction perpendicular to the main surface of the base substrate 1, and is on a side of the first electrode 21 away from the main surface of the base substrate 1; the first electrode 21 includes an upper surface away from the base substrate 1, and the inorganic insulation layer 3 covers the upper surface 21 A of the first electrode 21; and there is a first slit between the inorganic insulation layer 3 and the upper surface 21 A of the first electrode 21, and the width of the first slit is less than 0.2 μm. The inventor(s) of the present application improved the width of the above-mentioned first slit through the exploration of structural parameters and process parameters, so that the light-emitting substrate provided by the embodiment of the present disclosure has better performance. Compared with the case where there is a larger slit between the inorganic layer 3a and the upper surface of the first electrode 21a as illustrated in FIG. 13, in the light-emitting substrate provided by the embodiment of the present disclosure, the width of the first slit is less than 0.2 μm, which can increase the structural stability and mechanical strength of the electrical connection structure 2, improve the wrapping performance of the inorganic insulation layer 3 on the first electrode 21, and improve the pressure resistance and impact resistance of the electrical connection structure 2, which is beneficial to increasing the service life of the light-emitting substrate 10.

For example, referring to FIG. 17, the width of the first slit is less than 0.1 μm, so as to further increase the structural stability and mechanical strength of the electrical connection structure 2, further improve the wrapping performance of the inorganic insulation layer 3 on the first electrode 21, and further improve the pressure resistance and impact resistance of the electrical connection structure 2, which is beneficial to increasing the service life of the light-emitting substrate 10. In product testing, the light-emitting substrate with a first slit width of less than 0.1 μm has significantly better pressure resistance and impact resistance, which is beneficial to increasing the service life of the light-emitting substrate 10.

Further, referring to FIG. 17, for example, the width of the first slit may be less than 0.05 μm, which may further increase the structural stability and mechanical strength of the electrical connection structure 2, further improve the wrapping performance of the inorganic insulation layer 3 on the first electrode 21, and improve the pressure resistance and impact resistance of the electrical connection structure 2. In product testing, the light-emitting substrate with a first slit width of less than 0.05 μm has better pressure resistance and impact resistance, which is beneficial to increasing the service life of the light-emitting substrate 10.

It should be noted that the width of the first slit refers to a width of the first slit in the direction in which the inorganic insulation layer 3 and the upper surface 21A of the first electrode 21 are opposite to each other.

For example, the inorganic insulation layer 3 is directly and tightly attached to the upper surface 21 A of the first electrode 21, that is, there is no slit or impurity between the inorganic insulation layer 3 and the upper surface 21 A of the first electrode 21. In this way, the structural stability and mechanical strength of the electrical connection structure 2 may be increased, the pressure resistance and impact resistance of the electrical connection structure 2 may be improved, and the service life of the light-emitting substrate 10 may be increased.

FIG. 13 is a schematic diagram of a conductive structure of a light-emitting substrate in which there is a slit S between a metal electrode 21a and an inorganic layer 3a. In the light-emitting substrate 10 provided by the embodiment of the present disclosure, the slit S is described differently from the prior art, and is different from the “schematic diagram composed of line drawings” in the prior art. For example, in the light-emitting substrate 10 provided by the embodiment of the present disclosure, under a scanning electron microscope (SEM), the inorganic insulation layer 3 is also tightly attached to the upper surface 21A of the first electrode 21, without any bubbles, gaps, or other impurity substances between them, thereby achieving the ideal effect of improving the wrapping performance of the inorganic insulation layer 3 on the first electrode 21.

For example, referring to FIG. 17, the first electrode 21 further includes a side surface 21B intersecting with the upper surface 21A, the inorganic insulation layer 3 covers the side surface 21B of the first electrode 21, and there is a second slit between the inorganic insulation layer 3 and the side surface 21B of the first electrode 21, and the width of the second slit is less than 0.2 μm. The inventor(s) of the present application improved the width of the second slit through the exploration of structural parameters and process parameters, so that the light-emitting substrate provided by the embodiment of the present disclosure has better performance. Compared with the case where there is a larger slit between the inorganic layer 3a and the side surface of the first electrode 21a as illustrated in FIG. 13, in the light-emitting substrate provided by the embodiment of the present disclosure, the width of the second slit is less than 0.2 μm, which can further increase the structural stability and mechanical strength of the electrical connection structure 2, further improve the wrapping performance of the inorganic insulation layer 3 on the first electrode 21, and further improve the pressure resistance and impact resistance of the electrical connection structure 2, which is beneficial to increasing the service life of the light-emitting substrate 10.

For example, referring to FIG. 17, the width of the second slit is less than 0.1 μm, so as to further increase the structural stability and mechanical strength of the electrical connection structure 2, further improve the wrapping performance of the inorganic insulation layer 3 on the first electrode 21, and further improve the pressure resistance and impact resistance of the electrical connection structure 2, which is beneficial to increasing the service life of the light-emitting substrate 10. In product testing, the light-emitting substrate with a second slit width of less than 0.1 μm has significantly better pressure resistance and impact resistance, which is beneficial to increasing the service life of the light-emitting substrate 10.

Further, referring to FIG. 17, for example, the width of the second slit may be less than 0.05 μm, which may further increase the structural stability and mechanical strength of the electrical connection structure 2, further improve the wrapping performance of the inorganic insulation layer 3 on the first electrode 21, and improve the pressure resistance and impact resistance of the electrical connection structure 2. In product testing, the light-emitting substrate with a second slit width of less than 0.05 μm has better pressure resistance and impact resistance, which is beneficial to increasing the service life of the light-emitting substrate 10.

It should be noted that the width of the second slit refers to a width of the second slit in the direction in which the inorganic insulation layer 3 and the side surface 21B of the first electrode 21 are opposite to each other.

For example, the inorganic insulation layer 3 is tightly attached to the side surface 21B of the first electrode 21, without any bubbles, gaps, or other impurity substances between them, thereby achieving the ideal effect of improving the wrapping performance of the inorganic insulation layer 3 on the first electrode 21.

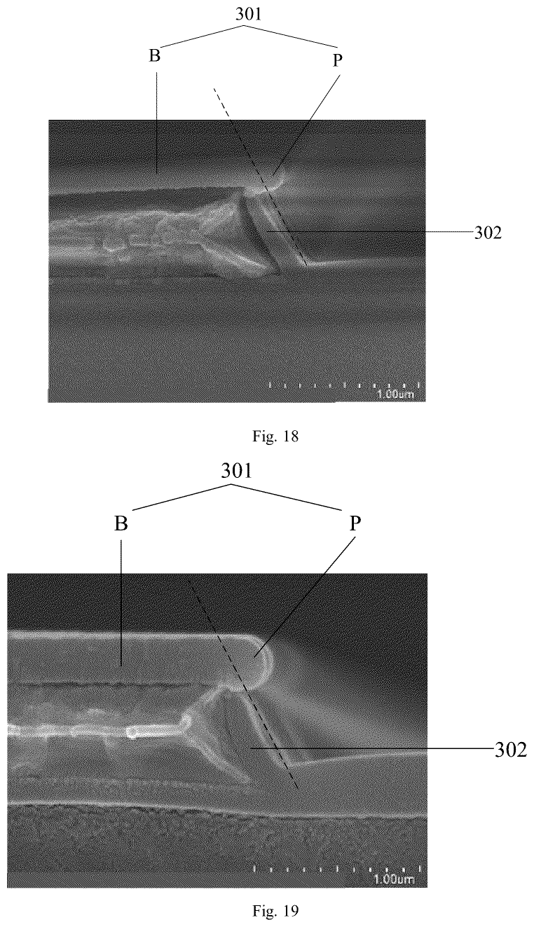

FIG. 18 is a SEM (scanning electron microscope) cross-sectional view of another electrical connection structure of a light-emitting substrate provided by one embodiment of the present disclosure. For example, referring to FIG. 18, the inorganic insulation layer 3 includes a top portion 301 and a side portion 302, the top portion 301 of the inorganic insulation layer 3 covers the upper surface, and the side portion 302 of the inorganic insulation layer 3 is connected to the top portion 301 of the inorganic insulation layer 3 and covers the side surface of the first electrode 21. The top portion 301 of the inorganic insulation layer 3 includes a main body portion B and a protrusion portion P, the main body portion B covers the upper surface of the first electrode 21, and the protrusion portion P extends from the main body portion B along a horizontal direction parallel to the main surface of the base substrate 1 and protrudes from the main body portion B and the side surface, that is, the surface of the side portion 302 of the inorganic insulation layer 3. For example, in FIG. 18, a virtual connection line is constructed from the bottom to the top of the outer side surface of the side portion 302 of the inorganic insulation layer 3, and the protrusion portion P is outside the virtual connection line.

For example, in the case where the thickness of the inorganic insulation layer 3 is within a preset range, as the thickness of the inorganic insulation layer 3 increases, the length of the protrusion portion P in the horizontal direction becomes smaller. The thickness of the inorganic insulation layer 3 refers to, for example, the thickness of the upper portion of the inorganic insulation layer 3 in a direction perpendicular to the main surface of the base substrate.

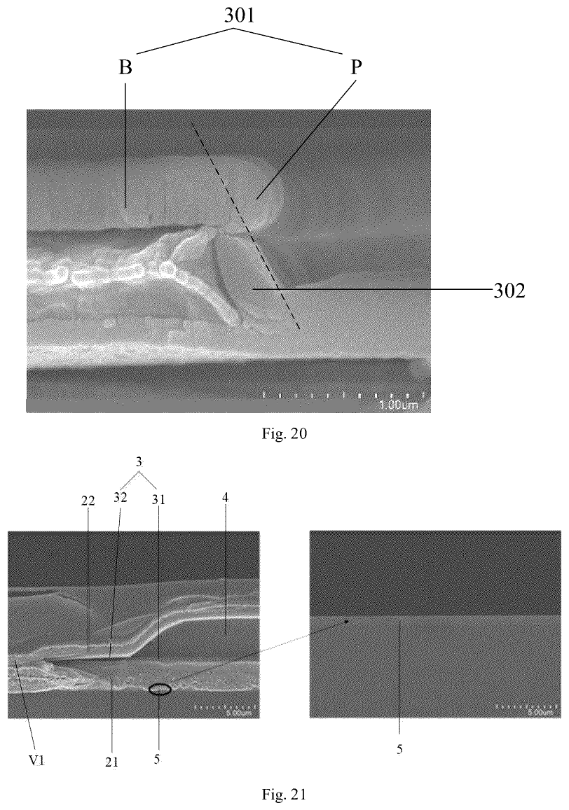

For example, the preset range includes at least 1200 angstroms to 3500 angstroms. The thickness of the inorganic insulation layer 3 is 1200 angstroms, 2400 angstroms, and 3500 angstroms in FIG. 18, FIG. 19, and FIG. 20, respectively. Taking the structures under these three thickness conditions as examples, as the thickness of the inorganic insulation layer 3 increases from 1200 angstroms to 3500 angstroms, the length of the protrusion portion P in the horizontal direction gradually becomes smaller.

For example, the top portion 301 of the inorganic insulation layer 3 covers the upper surface 21A of the first electrode 21, the side portion 302 of the inorganic insulation layer 3 is connected to the top portion 301 of the inorganic insulation layer 3, and the side portion 302 of the inorganic insulation layer 3 covers the side surface 21B of the first electrode 21. The inorganic insulation layer 3 includes an interface portion IP at the junction position of the top portion 301 and the side portion 302, the interface portion IP corresponds to the edge of the first electrode 21 away from the base substrate 1, and in the interface portion IP, the top portion 301 of the inorganic insulation layer 3 and the side portion 302 of the inorganic insulation layer 3 are continuously connected, and the interface portion IP is dense and has no cracks. The solution in the light-emitting substrate 10 provided by the embodiment of the present disclosure that “the top portion 301 of the inorganic insulation layer 3 and the side portion 302 of the inorganic insulation layer 3 are continuously connected, and the interface portion IP is dense and has no cracks” is different from the “schematic diagram composed of line drawings” in the prior art. For example, for the light-emitting substrate 10 provided by the embodiment of the present disclosure, under a scanning electron microscope (SEM), the inorganic insulation layer 3 is also tightly attached to the upper surface 21A of the first electrode 21, and there are no gaps or impurities composed of other substances between the inorganic insulation layer 3 and the upper surface 21A of the first electrode 21.

For example, the included angle between the surface of the side portion 302 of the inorganic insulation layer 3 and the main surface of the base substrate 1 is 50°-60°, and the thickness of the first electrode 21 is 2.7 μm; or, the included angle between the surface of the side portion 302 of the inorganic insulation layer 3 and the main surface of the base substrate 1 is 55°-65°, and the thickness of the first electrode 21 is 3.6 μm. In this way, the included angle between the surface of the side portion 302 of the inorganic insulation layer 3 and the main surface of the base substrate 1 is within a suitable range, which can prevent the inorganic insulation layer 3 from breaking and ensure that the inorganic insulation layer 3 has good wrapping properties for the first electrode 21.

For example, the electrical connection structure 2 further includes a buffer layer buffer, and the buffer layer buffer is stacked with the first electrode 21 in the vertical direction. In order to reduce the warping level of the base substrate 1, after a large number of experimental studies, the following thickness range and stress range of the buffer layer buffer are obtained, which can effectively reduce the warping level of the base substrate, facilitate the adhesion of each film layer of the electrical connection structure 2 on the base substrate 1, and reduce the warping of the electrical connection structure 2, thereby ensuring the reliability of the subsequent die-bonding operations for the light-emitting device and ensuring the stable operation of the light-emitting device.

For example, the thickness range of the buffer layer buffer is 2000 angstroms to 2800 angstroms, and the stress range of the buffer layer buffer is −360 Mpa to −440 Mpa; or
the thickness range of the buffer layer buffer is 3600 angstroms to 4500 angstroms, and the stress range of the buffer layer buffer is −360 Mpa to −440 Mpa; or
the thickness range of the buffer layer buffer is 4600 angstroms to 5400 angstroms, and the stress range of the buffer layer buffer is −360 Mpa to −440 Mpa; or
the thickness range of the buffer layer buffer is 5800 angstroms to 6200 angstroms, and the stress range of the buffer layer buffer is less than −800 Mpa.

Moreover, under the condition that the thickness range of the buffer layer buffer and the stress range of the buffer layer buffer mentioned above are met, the influence of the thickness of the first electrode 21 on the warping degree of the base substrate 1 and the electrical connection structure 2 is also explored, for example, the warping specification of the base substrate 1 is less than 0.2 mm. For example, the thickness of the first electrode 21 is 1.8 μm to 3.6 μm, and under the condition that the thickness range of the buffer layer buffer, the stress range of the buffer layer buffer and the thickness range of the first electrode 21 mentioned above are met, the warping level of the base substrate may be more effectively reduced, which facilitates the adhesion of each film layer of the electrical connection structure 2 on the base substrate 1, and reduces the warping of the electrical connection structure 2, thereby ensuring the reliability of the subsequent die-bonding operations for the light-emitting device and ensuring the stable operation of the light-emitting device.

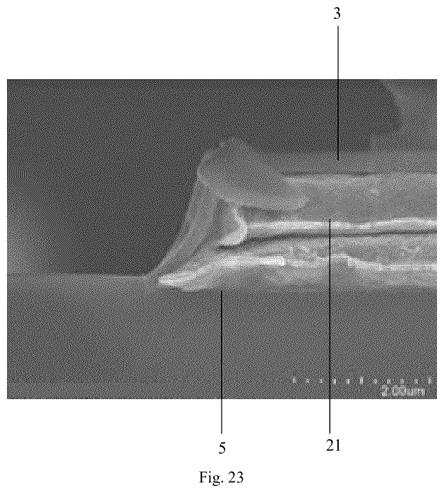

Exemplarily, FIG. 22-FIG. 23 are SEM (scanning electron microscope) cross-sectional views of electrical connection structures with different film layer parameters provided by one embodiment of the present disclosure. In the electrical connection structure illustrated in FIG. 22, the thickness of the buffer layer buffer is 2400 angstroms, and the material of the first electrode 21 is copper and the thickness is 1.8 μm; and in the electrical connection structure illustrated in FIG. 23, the thickness of the buffer layer buffer is 4000 angstroms, and the material of the first electrode 21 is copper and the thickness is 2.7 μm. In the structures illustrated in FIG. 22 and FIG. 23, the flatness of the base substrate and the electrical connection structure is good, and the inorganic insulation layer 3 provides good coverage over the first electrode 21.

For example, the inorganic insulation layer 3 includes an edge portion, and the edge portion is stacked and in contact with the buffer layer buffer in the vertical direction.

For example, the material of the inorganic insulation layer 3 includes at least one selected from a group consisting of silicon nitride, silicon oxide and silicon oxynitride; the material of the buffer layer buffer includes at least one selected from a group consisting of silicon nitride, silicon oxide and silicon oxynitride; and the material of the first electrode 21 is copper. For example, the material of the inorganic insulation layer is the same as the material of the buffer layer buffer. In particular, for the specific materials of the inorganic insulation layer 3 and the buffer layer buffer, the thickness range of the buffer layer buffer, the stress range of the buffer layer buffer and the thickness range of the first electrode 21 can achieve a better effect of effectively reducing the warping level of the base substrate.

For example, the base substrate 1 is a glass substrate, and the glass substrate does not include Na and Ca components. For example, the base substrate 1 adopts an SDL substrate, which can avoid that the glass itself has Na/Ca ions that precipitate and grow abnormally, so as to avoid corrosion of the conductive metal layer and bubbling defects, which seriously affects the reliability performance of the MLED light-emitting substrate.

FIG. 6 is a schematic plan view of an electrical connection structure of a light-emitting substrate provided by one embodiment of the present disclosure; and FIG. 7 is a schematic cross-sectional view along line A1-A2 in FIG. 6. The positional relationship between the electrical connection structures is expressed by combining the schematic diagrams illustrated in FIG. 6 to FIG. 7 with FIG. 17 to FIG. 20, but the morphological characteristics of the actual layer structure shall be based on FIG. 17 to FIG. 20.

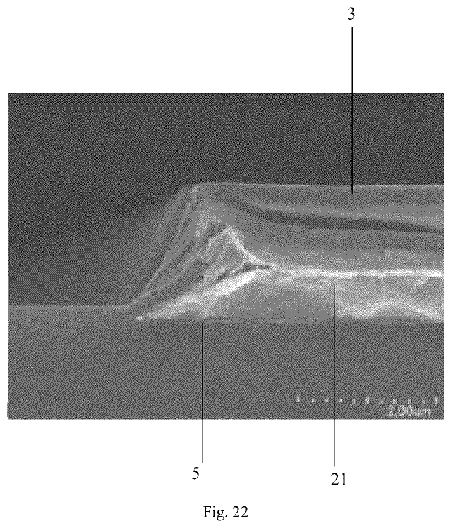

FIG. 21 is a SEM (scanning electron microscope) cross-sectional view of yet another electrical connection structure of a light-emitting substrate provided by one embodiment of the present disclosure, and FIG. 8 is another schematic cross-sectional view along line A1-A2 in FIG. 6; that is, FIG. 21 illustrates an actual structural diagram of an electrical connection structure, and FIG. 8 is a schematic diagram of the electrical connection structure. Referring to FIG. 21 and FIG. 8, for example, the electrical connection structure 2 further includes a second electrode 22, which is stacked with the first electrode 21 and the inorganic insulation layer 3 in the vertical direction, and is on a side of the inorganic insulation layer 3 away from the first electrode 21, and is electrically connected to the first electrode 21 through a first via hole V1 penetrating through the inorganic insulation layer 3.

For example, the inorganic insulation layer 3 includes a first sub-inorganic insulation layer 31 and a second sub-inorganic insulation layer 32 stacked on each other in the vertical direction, the second sub-inorganic insulation layer 32 is on a side of the first sub-inorganic insulation layer 31 away from the base substrate 1, and the first via hole V1 penetrates through the first sub-inorganic insulation layer 31 and the second sub-inorganic insulation layer 32.

For example, the thickness of the first sub-inorganic insulation layer 31 is greater than 4000 angstroms, so that the warping level of the base substrate and the electrical connection structure meets the requirements, ensuring the reliability of subsequent die bonding.

Referring to FIG. 7, the inorganic insulation layer 3 includes a first sub-portion 3a and a second sub-portion 3b arranged in the vertical direction D1, and the second sub-portion 3b is on a side of the first sub-portion 3a away from the base substrate 1; the first sub-portion 3a includes a first slope surface S1 surrounding the first via hole V1, and the second sub-portion 3b includes a second slope surface S2 surrounding the first via hole V1; the first electrode 21 includes a cover portion not exposed by the first via hole V1, the cover portion of the first electrode 21 includes an upper surface TS1 away from the base substrate 1, a first included angle θ1 is formed between the surface where the first slope surface S1 is located and the upper surface TS1 of the cover portion, and a second included angle θ2 is formed between the surface where the second slope surface S2 is located and the upper surface TS1 of the cover portion (represented by the included angle between a dashed line parallel to the upper surface TS1 of the cover portion and the surface where the second slope surface S2 is located in FIG. 7); and the second included angle θ2 is greater than the first included angle θ1, the first included angle θ1 is the slope angle of the first slope surface S1, and the second included angle θ2 is the slope angle of the second slope surface S2. Thus, the side wall of the inorganic insulation layer 3 surrounding the first via hole V1 (i.e., the hole wall of the first via hole V1) presents a double-step morphology, which prevents the slope angle of the entire side wall of the inorganic insulation layer 3 surrounding the first via hole V1 from being too large, thereby facilitating the adhesion of the second electrode 22 to the first slope surface S1 and the second slope surface S2, and avoiding the electrical and reliability defects caused by the breakage of the second electrode 22 at the hole wall of the first via hole V1. In addition, the double-step morphology may be manufactured by two dry etching processes, the first dry etching process uses an atmosphere with a high oxygen concentration, and the second dry etching process uses an atmosphere with a low oxygen concentration. Thus, not only can the double-step morphology structure be used to solve the problem that the second electrode 22 is easily broken at the position of the side wall of the inorganic insulation layer 3 surrounding the first via hole V1, but the two dry etching processes can also be used to avoid the problem that the first electrode 21 is over-oxidized under a high oxygen concentration after being exposed by the first via hole V0, thereby reducing the adhesion between the first electrode 21 and the second electrode, thereby solving the problem of poor bubbling between the second electrode 22 caused by the poor adhesion.

The second electrode 22 is continuous at the double step including the first slope surface S1 and the second slope surface S2, and covers the entire first via hole V0. The second electrode 22 has no break or crack, and no other impurities are mixed in the crack due to the crack.

For example, referring to FIG. 7, the thickness of the second sub-portion 3b in the vertical direction D1 is smaller than the thickness of the first sub-portion 3a in the vertical direction D1. In this way, the second sub-portion 3b corresponding to the second slope surface S2 having a larger slope angle has a smaller thickness, which facilitates the adhesion of the second electrode 22 to the first slope surface S1 and the second slope surface S2. Otherwise, even if the bubbling problem is solved, the adhesion effect between the second electrode 22 and the entire side wall (entire slope surface) of the inorganic insulation layer 3 surrounding the first via hole V1 is not ideal, and the electrical and reliability defects caused by the breakage of the second electrode 22 at the hole wall of the first via hole V1 are further avoided.

For example, referring to FIG. 7, the ratio of the thickness of the second sub-portion 3b in the vertical direction D1 to the thickness of the inorganic insulation layer 3 in the vertical direction D1 is less than or equal to ⅓. After experimental verification, meeting this condition can achieve a better effect of preventing the second electrode 22 from breaking at the hole wall of the first via hole V1, thereby obtaining a higher electrical reliability.

For example, a buffer layer buffer is provided on the main surface of the base substrate 1, and the first electrode 21, the second electrode 22, the inorganic insulation layer 3, etc. are all provided on the buffer layer buffer.

For example, the first included angle θ1 is in the range of 15° to 30°, and the second included angle θ2 is in the range of 50° to 80°. The inventor(s) of the present application found that the size of the first included angle θ1 and the size of the second included angle θ2 have a great influence on preventing the second electrode from being broken. After experimental exploration, a relatively stable and good effect may be obtained within the above angle range. The second included angle θ2 cannot be too large, so as to facilitate the adhesion of the second electrode to the second slope surface forming the second included angle and prevent the second electrode from being broken. In addition, the size of the first included angle θ1 should not be too small or too large. If the first included angle θ1 is too small, for example, less than 15°, it will cause the first slope surface forming the first included angle to be difficult to manufacture. If the first included angle is too large, for example, greater than 30°, in the case where the above-mentioned two dry etching processes are used to manufacture the first slope surface and the second slope surface, the second included angle will be larger, which is not facilitate to the adhesion of the second electrode to the first slope surface, nor to the adhesion of the second electrode to the second slope surface, so that the second electrode is prone to breakage at the positions of the first slope surface and the second slope surface.

For example, referring to FIG. 7, a portion of the second electrode 22 in the first via hole V1 includes a lower surface and a side surface; the lower surface of the second electrode 22 is in contact with the first electrode 21 and there are no bubbles, gaps or impurities between the lower surface of the second electrode 22 and the first electrode 21; and the side surface of the second electrode 22 is in contact with the first slope surface S1 and the second slope surface S2 and there are no bubbles, gaps or impurities between the side surface of the second electrode 22 and the first slope surface S1 as well as the second slope surface S2. Here, “impurities” refer to substances other than the target layers of the first electrode 21, the second electrode 22 and the inorganic insulation layer 3 formed in the process.

As illustrated in FIG. 7, the portion of the second electrode 22 covering the first slope surface S1 and the second slope surface S2 away from the surface of the base substrate 1 includes a slope, and an included angle between the slope and the plane where the main surface of the base substrate 1 is located is the slope angle of the second electrode 22. For example, the slope angle of the second electrode 22 is less than 90°, for example, 30°-60°.

For example, the material of the inorganic insulation layer 3 includes at least one selected from a group consisting of silicon nitride, silicon oxide and silicon oxynitride. The materials of the first electrode 21 and the second electrode 22 are metal materials, and the metal materials include metals or alloys, for example, are both copper. Copper is a material with good conductivity, easy to obtain and manufacture, and is currently used in the conductive connection structure of the display substrate, so it is a preferred material. Alternatively, the materials of the first electrode 21 and the second electrode 22 may be manganese, chromium, copper alloy, manganese alloy, etc. However, the materials of the first electrode and the second electrode are not limited to the types listed above, and the embodiments of the present disclosure are not limited to this.

FIG. 8 is another schematic cross-sectional view along line A1-A2 in FIG. 6. The embodiment illustrated in FIG. 8 has the following differences from the embodiment illustrated in FIG. 7.

For example, referring to FIG. 8, for example, the inorganic insulation layer 3 includes a first sub-inorganic insulation layer 31 and a second sub-inorganic insulation layer 32 stacked on each other in the vertical direction D1, the second sub-inorganic insulation layer 32 is on a side of the first sub-inorganic insulation layer 31 away from the base substrate 1, and the first via hole V1 penetrates through the first sub-inorganic insulation layer 31 and the second sub-inorganic insulation layer 32; the second sub-inorganic insulation layer 32 includes an upper portion 32t and a lower portion 32b, the lower portion 32t is in contact with the first sub-inorganic insulation layer 31, the upper portion 32t is on a side of the lower portion 32b away from the first sub-inorganic insulation layer 31, the upper portion 32t serves as the second sub-portion including the second slope surface S2, and a whole structure constituted by the lower portion 32b and the first sub-inorganic insulation layer 31 serves as the first sub-portion including the first slope surface S1. The dashed line 1 in FIG. 8 is used as a schematic boundary between the upper portion 32t and the lower portion 32b. In the structure illustrated in FIG. 8, the inorganic insulation layer 3 is composed of two sub-inorganic insulation layers. The side wall (i.e., the hole wall of the first via hole V1) of the inorganic insulation layer 3 surrounding the first via hole V1 also presents a double-step morphology. Similar to the technical effect illustrated in FIG. 7, the embodiment illustrated in FIG. 8 may also prevent the slope angle of the entire side wall of the inorganic insulation layer 3 surrounding the first via hole V1 from being too large, thereby facilitating the adhesion of the second electrode 22 to the first slope surface S1 and the second slope surface S2, and avoiding the electrical and reliability defects caused by the breakage of the second electrode 22 at the hole wall of the first via hole V1. In addition, the double-step morphology may be manufactured by two dry etching processes. The first dry etching process uses an atmosphere with a high oxygen concentration, and the second dry etching process uses an atmosphere with a low oxygen concentration to solve the problem of poor bubbling between the second electrodes 22 caused by this.

For example, the material of the first sub-inorganic insulation layer 31 is the same as the material of the second sub-inorganic insulation layer 32. For example, the material of the first sub-inorganic insulation layer 31 and the material of the second sub-inorganic insulation layer 32 both include at least one selected from a group consisting of silicon nitride, silicon oxide and silicon oxynitride.

For example, referring to FIG. 8, the light-emitting substrate 10 further includes a first organic insulation layer 4, which is between the first sub-inorganic insulation layer 31 and the second sub-inorganic insulation layer 32, and includes a second via hole V2. The orthographic projection of the first via hole V1 on the base substrate 1 falls within the orthographic projection of the second via hole V2 on the base substrate 1. The first organic insulation layer 4 includes an upper surface 41 away from the base substrate 1 and a side surface 42 facing the first via hole V1. The second sub-inorganic insulation layer 32 covers the upper surface 41 and the side surface 42 of the first organic insulation layer 4. A portion of the first sub-inorganic insulation layer 31 close to the first via hole V1 includes a first edge portion 31e exposed by the second via hole V2, and a portion of the second sub-inorganic insulation layer 32 covering the side surface 42 of the first organic insulation layer 4 is a second edge portion 32e. The second edge portion 32e further covers the first edge portion 31e and is in contact with the first edge portion 31e. A structure constituted by the first edge portion 31e and the second edge portion 32e includes the first slope surface S1 and the second slope surface S2. Generally, after forming the first sub-inorganic insulation layer 31, the first organic insulation layer 4 is formed, and then the second sub-inorganic insulation layer 32 is formed. The second sub-inorganic insulation layer 32 covers the first organic insulation layer 4, and the second edge portion 32e of the second sub-inorganic insulation layer 32 wraps the edge of the first organic insulation layer 4, which can protect the first organic insulation layer 4 from being etched in the subsequent dry etching process of the inorganic insulation layer 3 composed of the first sub-inorganic insulation layer 31 and the second sub-inorganic insulation layer 32. The second electrode 22 is continuous at the double step including the first slope surface S1 and the second slope surface S2, the second electrode 22 covers the entire first via hole V0, and the second electrode 22 has no breakage, no cracks, and no other impurities are mixed in the cracks due to the cracks.

It should be noted that FIG. 8 is a cross-sectional view. In fact, the first edge portion 31e is in a ring shape surrounding the first via hole V1, for example, a ring shape closed around the entire first via hole V1.

For example, referring to FIG. 8, the first slope surface S1 includes the junction position of the first edge portion 31e and the second edge portion 32e, and the slope angle of the first slope surface S1 at the junction position is equal to the slope angle of the entire first slope surface S1. That is, the entire first slope surface S1 is a smooth transition, and there is no jump at the junction position, so as to facilitate the adhesion and continuity of the second electrode 22 on the first slope surface S1.

Other features illustrated in FIG. 8, such as the range of the first included angle θ1, the range of the second included angle θ2, the range of the slope angle of the second electrode 22, etc., and the corresponding technical effects are the same as those in the embodiment illustrated in FIG. 7, and the previous description can be referred to and will not be repeated here.

For example, the warping level of the base substrate 1 adopting the above-mentioned design is less than 0.2 mm, for example, less than 0.1 mm, which can effectively reduce the warping level, facilitate the adhesion of each film layer of the electrical connection structure 2 on the base substrate 1, and reduce the warping of the electrical connection structure 2, thereby ensuring the reliability of the subsequent die-bonding operations for the light-emitting device and ensuring the stable operation of the light-emitting device.

The warping level refers to the height difference between the highest point of the main surface of the base substrate and the lowest point of the base substrate in the direction perpendicular to the main surface of the base substrate.

The electrical connection structure illustrated in FIG. 9A may be any electrical connection structure of the light-emitting substrate provided by the embodiments of the present disclosure, for example, it may also be the electrical connection structure illustrated in FIG. 17 or FIG. 18 or FIG. 19 or FIG. 20 or FIG. 21. For a specific description, please refer to the previous description of FIG. 9A, which will not be repeated here.

At least one embodiment of the present disclosure provides a method for manufacturing a light-emitting substrate 10, and the method includes: providing a base substrate 1, in which the base substrate 1 has a main surface and includes a light-emitting region LR and a non-light-emitting region NLR at least partially surrounding the light-emitting region LR; providing a light-emitting device on the main surface of the base substrate 1, in which the light-emitting device is in the light-emitting region LR; and forming an electrical connection structure 2 on the main surface of the base substrate 1, which includes: forming a first electrode 21, in which the first electrode 21 is on the main surface of the base substrate 1; forming an inorganic insulation layer 3, in which the inorganic insulation layer 3 is stacked with the first electrode 21 in a vertical direction perpendicular to the main surface of the base substrate 1, and is on a side of the first electrode 21 away from the main surface of the base substrate 1; and the first electrode 21 includes an upper surface away from the base substrate 1, the inorganic insulation layer 3 covers the upper surface of the first electrode 21, and the inorganic insulation layer 3 is directly and tightly attached to the upper surface of the first electrode 21.

Specifically, the above-mentioned structure may be formed layer by layer using conventional processes, and the specific structural features may refer to the description in the previous embodiment, which will not be repeated here.

For example, in the method for manufacturing the light-emitting substrate 10 provided in the embodiment of the present disclosure, the inorganic insulation layer 3 is formed by chemical vapor deposition. Through experimental exploration and comparison, the inorganic insulation layer 3 formed by chemical vapor deposition (CVD) can form a structure as illustrated in FIG. 17, ensuring that the lower surface of the second electrode 22 is attached to the first electrode 21 and there are no bubbles, gaps or impurities between the second electrode 22 and the first electrode 21; the inorganic insulation layer 3 is closely attached to the side surface 21B of the first electrode 21 and there are no bubbles, gaps and impurities between the inorganic insulation layer 3 and the side surface 21B of the first electrode 21; and the included angle between the surface of the side portion 302 of the inorganic insulation layer 3 and the main surface of the base substrate 1 is smaller, and the included angle is within a suitable range, which can prevent the inorganic insulation layer 3 from breaking and ensure that the inorganic insulation layer 3 has good wrapping properties for the first electrode 21. FIG. 13 is a structure of an inorganic insulation layer formed by physical vapor deposition (PVD). In FIG. 13, first, there is a slit between the metal electrode 21a in the conductive structure and the inorganic layer 3a; second, after testing and comparison, the included angle between the surface of the side portion of the inorganic layer in FIG. 13 and the main surface of the base substrate is also large, which easily leads to the fracture of the inorganic layer; third, in FIG. 13, at the interface portion corresponding to FIG. 17, the upper portion and side portion of the inorganic layer have cracks, and the wrapping effect on the metal electrode 21a is not as good as the continuous interface portion in FIG. 17. It may be seen that compared with the inorganic insulation layer 3 formed by chemical vapor deposition (CVD), the effect of the inorganic insulation layer formed by physical vapor deposition (PVD) is poor.

For example, the buffer layer buffer is also formed by chemical vapor deposition (CVD). It can achieve good particle control effect, and the formed film layer has strong adhesion, low warpage, higher stability, and increased durability.

In addition, in the light-emitting substrate of Mini LED or Micro LED, the buffer layer buffer or inorganic insulation layer 3 is formed by PVD process. It is difficult to control particles during the deposition process, especially in the case where the thickness of the buffer layer buffer or inorganic insulation layer 3 is greater than or equal to 3600 angstroms, the particle control is more difficult; thus, the particle control effect of the first electrode 21 is likely to exceed the requirements, and the film quality is poor. Relatively speaking, CVD is easier to adjust the film quality of the film layer than PVD, for example, the process adjustment margin is larger in terms of particle control, stress adjustment, adhesion optimization, acid washing resistance, etc. And in terms of cost, the CVD process has lower manufacturing cost than the PVD process. For example, in the case where only the first electrode 21 is present without the second electrode 22, and the thickness of the first electrode 21 is 1.8 μm, the manufacturing cost of the CVD process is about 12% lower than that of the PVD process. In the case where only the first electrode 21 is present without the second electrode 22, and the thickness of the first electrode 21 is 2.7 μm, the manufacturing cost of the CVD process is even lower.

What have been described above are only specific implementations of the present disclosure, the protection scope of the present disclosure is not limited thereto, and the protection scope of the present disclosure should be based on the protection scope of the claims.

1. A light-emitting substrate, comprising:
a base substrate, having a main surface, and comprising a light-emitting region and a non-light-emitting region at least partially surrounding the light-emitting region;
a light-emitting device, provided on the main surface of the base substrate and in the light-emitting region; and
an electrical connection structure, wherein the electrical connection structure comprises:
a first electrode on the main surface of the base substrate;
an inorganic insulation layer, stacked with the first electrode in a vertical direction perpendicular to the main surface of the base substrate, and on a side of the first electrode away from the main surface of the base substrate, wherein the inorganic insulation layer comprises a first via hole exposing the first electrode;
a second electrode, stacked with the first electrode and the inorganic insulation layer in the vertical direction, and on a side of the inorganic insulation layer away from the first electrode, and electrically connected to the first electrode through the first via hole,
wherein the inorganic insulation layer comprises a first sub-portion and a second sub-portion that are arranged in the vertical direction, and the second sub-portion is on a side of the first sub-portion away from the base substrate; the first sub-portion comprises a first slope surface surrounding the first via hole, and the second sub-portion comprises a second slope surface surrounding the first via hole;
the first electrode comprises a cover portion not exposed by the first via hole, the cover portion of the first electrode comprises an upper surface away from the base substrate, a first included angle is between a surface where the first slope surface is located and the upper surface of the cover portion, a second included angle is between a surface where the second slope surface is located and the upper surface of the cover portion, and the second included angle is greater than the first included angle; and
the electrical connection structure comprises a first electrical connection structure, the first electrical connection structure comprises the first electrode and the second electrode, and the first electrode and the second electrode of the first electrical connection structure are configured to provide an electrical signal to the light-emitting device for driving the light-emitting device to emit light.

2. The light-emitting substrate according to claim 1, wherein a thickness of the second sub-portion in the vertical direction is less than a thickness of the first sub-portion in the vertical direction.

3. The light-emitting substrate according to claim 2, wherein a ratio of the thickness of the second sub-portion in the vertical direction to a thickness of the inorganic insulation layer in the vertical direction is less than or equal to ⅓.

4. The light-emitting substrate according to claim 1, wherein the inorganic insulation layer comprises a first sub-inorganic insulation layer and a second sub-inorganic insulation layer stacked on each other in the vertical direction;
the second sub-inorganic insulation layer is on a side of the first sub-inorganic insulation layer away from the base substrate, and the first via hole penetrates through the first sub-inorganic insulation layer and the second sub-inorganic insulation layer; and
the second sub-inorganic insulation layer comprises an upper portion and a lower portion, the lower portion is in contact with the first sub-inorganic insulation layer, the upper portion is on a side of the lower portion away from the first sub-inorganic insulation layer, the upper portion serves as the second sub-portion, and a whole structure constituted by the lower portion and the first sub-inorganic insulation layer serves as the first sub-portion.

5. The light-emitting substrate according to claim 1, further comprising:
a first organic insulation layer, between the first sub-inorganic insulation layer and the second sub-inorganic insulation layer, and comprising a second via hole,
wherein an orthographic projection of the first via hole on the base substrate falls within an orthographic projection of the second via hole on the base substrate, the first organic insulation layer comprises an upper surface away from the base substrate and a side surface facing the first via hole, and the second sub-inorganic insulation layer covers the upper surface and the side surface of the first organic insulation layer; and
a portion of the first sub-inorganic insulation layer close to the first via hole comprises a first edge portion exposed by the second via hole, a portion of the second sub-inorganic insulation layer covering the side surface of the first organic insulation layer is a second edge portion, the second edge portion further covers the first edge portion and is in contact with the first edge portion, and a whole structure constituted by the first edge portion and the second edge portion comprises the first slope surface and the second slope surface.

6. The light-emitting substrate according to claim 5, wherein the first included angle is a slope angle of the first slope surface, and the second included angle is a slope angle of the second slope surface; and
the first slope surface comprises a junction position of the first edge portion and the second edge portion, and a slope angle of the first slope surface at the junction position is equal to a slope angle of the entire first slope surface.

7. The light-emitting substrate according to claim 1, wherein the first included angle is in a range of 15° to 30°, and the second included angle is in a range of 50° to 80°.

8. The light-emitting substrate according to claim 1, wherein a portion of the second electrode in the first via hole comprises a lower surface and a side surface;
the lower surface of the second electrode is in contact with the first electrode, and no bubbles, gaps or impurities are between the lower surface of the second electrode and the first electrode; and
the side surface of the second electrode is in contact with both the first slope surface and the second slope surface, and no bubbles, gaps or impurities are between the side surface of the second electrode and the first slope surface as well as the second slope surface.

9. The light-emitting substrate according to claim 1, wherein a material of the inorganic insulation layer comprises at least one selected from a group consisting of silicon nitride, silicon oxide and silicon oxynitride, and materials of the first electrode and the second electrode are both copper.

10. The light-emitting substrate according to claim 1, wherein the light-emitting device comprises a first electrode pin and a second electrode pin;
the light-emitting substrate further comprises a circuit board in the non-light-emitting region, the first electrode of the first electrical connection structure is electrically connected to the circuit board to receive a power signal from the circuit board, the second electrode of the first electrical connection structure is electrically connected to the first electrode pin of the light-emitting device to provide the power signal to the light-emitting device, and the power signal is the electrical signal used to drive the light-emitting device to emit light.

11. The light-emitting substrate according to claim 10, wherein the light-emitting substrate comprises a first conductive layer and a second conductive layer, the first conductive layer comprises the first electrode, and the second conductive layer comprises the second electrode;
the light-emitting substrate further comprises a driving circuit, and the driving circuit is at least partially in the light-emitting region; and
the second conductive layer further comprises a connection electrode, a first end of the connection electrode is electrically connected to the driving circuit, a second end of the connection electrode is electrically connected to the second electrode pin of the light-emitting device to provide a light-emitting driving signal to the light-emitting device, and the light-emitting device is driven by the power signal and the light-emitting driving signal to emit light.

12. The light-emitting substrate according to claim 1, wherein the light-emitting substrate comprises a plurality of the electrical connection structures, the plurality of the electrical connection structures further comprise a second electrical connection structure, and the second electrical connection structure comprises the first electrode and the second electrode of the electrical connection structure;
the light-emitting substrate further comprises a driving circuit, and the driving circuit is at least partially in the light-emitting region; the light-emitting substrate comprises a light-emitting array, the light-emitting array comprises a plurality of light-emitting units arranged in an array, each light-emitting unit comprises a plurality of the light-emitting devices, and the driving circuit is provided corresponding to each light-emitting unit to control light-emitting condition of the light-emitting device of the each light-emitting unit; the plurality of light-emitting units of the light-emitting array comprise a first light-emitting unit and a second light-emitting unit that are in a same column;
the first electrode of the second electrical connection structure is electrically connected to the circuit board to receive a light-emitting control signal from the circuit board, the second electrode of the second electrical connection structure is electrically connected to an input terminal of the driving circuit corresponding to the first light-emitting unit, and the light-emitting control signal comprises a light-emitting driving signal for controlling light-emitting state of the light-emitting device and/or a timing control signal for controlling the light-emitting device to emit light;
the plurality of the electrical connection structures further comprise a third electrical connection structure, and the third electrical connection structure comprises the first electrode and the second electrode of the electrical connection structure; the second electrode of the third connection structure is electrically connected to an output terminal of the driving circuit corresponding to the first light-emitting unit, and the first electrode of the third electrical connection structure is electrically connected to an input terminal of the driving circuit corresponding to the second light-emitting unit to provide the light-emitting control signal to the second light-emitting unit.

13. The light-emitting substrate according to claim 12, wherein the plurality of the electrical connection structures further comprise a fourth electrical connection structure, and the fourth electrical connection structure comprises the first electrode and the second electrode of the electrical connection structure; and
the first electrode of the fourth electrical connection structure is grounded, and the second electrode of the fourth electrical connection structure is electrically connected to a ground signal input terminal of the driving circuit.

14. The light-emitting substrate according to claim 1, wherein the light-emitting device is a mini light-emitting diode (referred to as Mini LED) or a micro light-emitting diode (referred to as Micro LED).

15. A display device, comprising the light-emitting substrate according to claim 1, wherein the light-emitting substrate is a display substrate, the light-emitting region is a display region and comprises a sub-pixel, and the sub-pixel comprises the light-emitting device; the electrical signal provided by the first electrode and the second electrode of the first electrical connection structure to the light-emitting device for driving the light-emitting device to emit light is a display driving signal to drive the light-emitting device to display an image; or
the light-emitting substrate serves as a backlight source of the display device and is configured to provide light for display to the display substrate.

16. A method for manufacturing a light-emitting substrate, comprising:
providing a base substrate, wherein the base substrate has a main surface, and comprises a light-emitting region and a non-light-emitting region at least partially surrounding the light-emitting region;
providing a light-emitting device on the main surface of the base substrate, wherein the light-emitting device is in the light-emitting region; and
forming an electrical connection structure on the main surface of the base substrate, comprising:
forming a first electrode on the main surface of the base substrate;
forming an inorganic insulation layer, wherein the inorganic insulation layer is stacked with the first electrode in a vertical direction perpendicular to the main surface of the base substrate, and is on a side of the first electrode away from the main surface of the base substrate;
forming a first via hole penetrating through the inorganic insulation layer, wherein the first via hole exposes the first electrode; and
forming a second electrode, wherein the second electrode is stacked with the first electrode and the inorganic insulation layer in the vertical direction and is on a side of the inorganic insulation layer away from the first electrode, and is electrically connected to the first electrode through the first via hole;
wherein the inorganic insulation layer comprises a first sub-portion and a second sub-portion that are arranged in the vertical direction, and the second sub-portion is on a side of the first sub-portion away from the base substrate; the first sub-portion comprises a first slope surface surrounding the first via hole, and the second sub-portion comprises a second slope surface surrounding the first via hole;
the first electrode comprises a cover portion not exposed by the first via hole, the cover portion of the first electrode comprises an upper surface away from the base substrate, a first included angle is formed between a surface where the first slope surface is located and the upper surface of the cover portion, a second included angle is formed between a surface where the second slope surface is located and the upper surface of the cover portion, and the second included angle is greater than the first included angle; and
the electrical connection structure comprises a first electrical connection structure, the first electrical connection structure comprises the first electrode and the second electrode, and the first electrode and the second electrode of the first electrical connection structure are configured to provide an electrical signal to the light-emitting device for driving the light-emitting device to emit light.

17. A method for manufacturing a light-emitting substrate, comprising:
providing a base substrate, wherein the base substrate has a main surface, and comprises a light-emitting region and a non-light-emitting region at least partially surrounding the light-emitting region;
providing a light-emitting device on the main surface of the base substrate, wherein the light-emitting device is in the light-emitting region; and
forming an electrical connection structure on the main surface of the base substrate, comprising:
forming a first electrode on the main surface of the base substrate;
forming an inorganic insulation layer, wherein the inorganic insulation layer is stacked with the first electrode in a vertical direction perpendicular to the main surface of the base substrate, and is on a side of the first electrode away from the main surface of the base substrate;
forming a first via hole penetrating through the inorganic insulation layer, wherein the first via hole exposes the first electrode; and
forming a second electrode, wherein the second electrode is stacked with the first electrode and the inorganic insulation layer in the vertical direction and is on a side of the inorganic insulation layer away from the first electrode, and is electrically connected to the first electrode through the first via hole;
wherein the inorganic insulation layer comprises a first sub-portion and a second sub-portion that are arranged in the vertical direction, and the second sub-portion is on a side of the first sub-portion away from the base substrate; the first sub-portion comprises a first slope surface surrounding the first via hole, and the second sub-portion comprises a second slope surface surrounding the first via hole;
the first electrode comprises a cover portion not exposed by the first via hole, the cover portion of the first electrode comprises an upper surface away from the base substrate, a first included angle is formed between a surface where the first slope surface is located and the upper surface of the cover portion, a second included angle is formed between a surface where the second slope surface is located and the upper surface of the cover portion, and the second included angle is greater than the first included angle;
forming the inorganic insulation layer comprises:
forming an inorganic material layer, and performing dry etching on the inorganic material layer;
the dry etching comprises:
in a first dry etching stage, performing dry etching on the inorganic material layer under a first oxygen concentration condition; and
in a second dry etching stage after the first dry etching stage, continuing to perform dry etching on the inorganic material layer after the first dry etching stage under a second oxygen concentration condition,
wherein gases used in both the first dry etching stage and the second dry etching stage comprise oxygen, an oxygen concentration of the gas used in the first dry etching stage is the first oxygen concentration, an oxygen concentration of the gas used in the second dry etching stage is the second oxygen concentration, and the first oxygen concentration is greater than the second oxygen concentration.

18. The method for manufacturing a light-emitting substrate according to claim 17, wherein forming the inorganic insulation layer comprises:
forming a first sub-inorganic material layer after forming the first electrode;
forming an organic insulation layer, and forming a second via hole penetrating through the organic insulation layer, wherein an orthographic projection of the first via hole on the base substrate falls within an orthographic projection of the second via hole on the base substrate, and the first organic insulation layer comprises an upper surface away from the base substrate and a side surface facing the first via hole;
forming a second sub-inorganic material layer, wherein the second sub-inorganic material layer is stacked and in contact with the first sub-inorganic material layer in the vertical direction, and s structure constituted by the first sub-inorganic material layer and the second sub-inorganic material layer serves as the inorganic material layer; and
performing the dry etching on the inorganic material layer composed of the first sub-inorganic material layer and the second sub-inorganic material layer, wherein the dry etching comprises the first dry etching stage and the second dry etching stage.

19. The method for manufacturing a light-emitting substrate according to claim 17,
wherein in the first dry etching stage and the second dry etching stage, gases used for dry etching comprise oxygen and an auxiliary gas, and the oxygen concentration is a ratio of the oxygen to a total amount of the oxygen and the auxiliary gas; and
the first oxygen concentration ranges from 60% to 80%, and the second oxygen concentration ranges from 8% to 25%;
a duration of the second dry etching stage is less than a duration of the first dry etching stage;
at the end of the first dry etching stage, the upper surface of the first electrode is not yet exposed, and the method then enters the second dry etching stage at this time; or
at the end of the first dry etching stage, the upper surface of the first electrode is just exposed, the method then enters the second dry etching stage at this time.

20. (canceled)

21. The method for manufacturing a light-emitting substrate according to claim 17,
wherein at the end of the first dry etching stage, the upper surface of the first electrode is not yet exposed, and the method then enters the second dry etching stage at this time; or
at the end of the first dry etching stage, the upper surface of the first electrode is just exposed, the method then enters the second dry etching stage at this time.
